(19) United States
(12) Patent Application Publication
(10) Pub. No.: US 2024/0203812 A1
(43) Pub. Date: Jun. 20, 2024

(54) SEMICONDUCTOR DEVICE

(71) Applicant: RENESAS ELECTRONICS CORPORATION, Tokyo (JP)

(72) Inventors: Takamichi HOSOKAWA, Tokyo (JP); Kazuhiro MITAMURA, Tokyo (JP); Fumio MURAKAMI, Tokyo (JP); Yuji KAYASHIMA, Tokyo (JP); Yoshihiro MASUMURA, Tokyo (JP)

(21) Appl. No.: 18/067,375

(22) Filed: Dec. 16, 2022

(51) Int. Cl. H01L 23/31; H01L 23/00; H01L 23/29; H01L 23/498; H01L 25/065

(52) U.S. Cl. CPC H01L 23/315; H01L 23/295; H01L 23/49838; H01L 23/49861; H01L 24/32; H01L 24/48; H01L 24/73; H01L 25/0655; H01L 2224/32245; H01L 2224/48011; H01L 2224/48091; H01L 2224/48101; H01L 2224/48137; H01L 2224/48245; H01L 2224/73265; H01L 2924/1811; H01L 2924/1815; H01L 2924/182; H01L 2924/186; H01L 2924/30205; H01L 2924/37001

(57) ABSTRACT

A semiconductor device includes a first chip mounting portion, a second chip mounting portion, a first semiconductor chip mounted on the first chip mounting portion, a second semiconductor chip mounted on the second chip mounting portion, a plurality of lead portions, and a sealing portion sealing them. The sealing portion has a first main surface and a second main surface opposite the first main surface. A groove portion is formed in the sealing portion at the first main surface. At the first main surface of the sealing portion, each of the first chip mounting portion and the second chip mounting portion is exposed from the sealing portion. At the first main surface of the sealing portion, the groove portion is formed between an exposed portion of the first chip mounting portion and an exposed portion of the second chip mounting portion.

### BACKGROUND

The present invention relates to a semiconductor device, and can be suitably used in, for example, a semiconductor device in which two semiconductor chips are resin-sealed.

A semiconductor package is manufactured by mounting a semiconductor chip on a die pad, electrically connecting pads of the semiconductor chip and leads with wires, and sealing them with a resin.

Here, there are disclosed techniques listed below.
[Patent Document 1] Japanese Unexamined Patent Application Publication No. 2013-128040

Patent Document 1 discloses that a discharge occurs between a high-voltage terminal and a low-voltage terminal, which are exposed from a sealing body of a semiconductor device.

### SUMMARY

In a semiconductor device in which a first semiconductor chip and a second semiconductor chip are mounted on a first die pad and a second die pad, respectively, and in which the first semiconductor chip and the second semiconductor chip are resin-sealed, when a discharge occurs between the first die pad and the second die pad, which are exposed from a resin sealing body, a leakage current is generated between the first die pad and the second die pad. Given this leads to a deterioration in the performance of the semiconductor device, it is desired to be avoided the discharge.

Other objects and novel features will become apparent from the description of this specification and the accompanying drawings.

According to one embodiment, a semiconductor device according to one embodiment, includes a first chip mounting portion, a second chip mounting portion, a first semiconductor chip mounted on the first chip mounting portion, a second semiconductor chip mounted on the second chip mounting portion, a plurality of lead portions, and a sealing portion sealing them. The sealing portion has a first main surface and a second main surface opposite the first main surface. A groove portion is formed in the sealing portion at the first main surface. At the first main surface of the sealing portion, each of the first chip mounting portion and the second chip mounting portion is exposed from the sealing portion. At the first main surface of the sealing portion, the groove portion is formed between an exposed portion of the first chip mounting portion and an exposed portion of the second chip mounting portion.

### BRIEF DESCRIPTION OF THE DRAWINGS

FIG. 1 is a plan view of a semiconductor device according to an embodiment 1.

FIG. 2 is a plan view of the semiconductor device according to the embodiment 1.

FIG. 3 is a perspective plan view of the semiconductor device according to the embodiment 1.

FIG. 4 is a cross-sectional view of the semiconductor device according to the embodiment 1.

FIG. 5 is a cross-sectional view showing a state that the semiconductor device according to the embodiment 1 is mounted on a mounting substrate.

FIG. 6 is a cross-sectional view of a semiconductor device according to an examined example 1.

FIG. 7 is a cross-sectional view of a semiconductor device according to an examined example 2.

FIG. 8 is a cross-sectional view of a semiconductor device according to an examined example 3.

FIG. 9 is a cross-sectional view of a semiconductor device according to an examined example 4.

FIG. 10 is a plan view of a semiconductor device according to an embodiment 1.

FIG. 11 is a plan view of the semiconductor device according to the embodiment 2.

FIG. 12 is a cross-sectional view of the semiconductor device according to the embodiment 2.

FIG. 13 is a cross-sectional view showing a state that the semiconductor device according to the embodiment 2 is mounted on a mounting substrate.

FIG. 14 is a plan view of a semiconductor device according to an embodiment 3.

FIG. 15 is a plan view of the semiconductor device according to the embodiment 3.

FIG. 16 is a cross-sectional view of the semiconductor device according to the embodiment 3.

FIG. 17 is a cross-sectional view showing a state that the semiconductor device according to the embodiment 3 is mounted on a mounting substrate.

FIG. 18 is a plan view of a semiconductor device according to an embodiment 4.

FIG. 19 is a plan view of the semiconductor device according to the embodiment 4.

FIG. 20 is a cross-sectional view of the semiconductor device according to the embodiment 4.

FIG. 21 is a cross-sectional view showing a state that the semiconductor device according to the embodiment 4 is mounted on a mounting substrate.

FIG. 22 is a plan view of a semiconductor device according to an embodiment 5.

FIG. 23 is a plan view of the semiconductor device according to the embodiment 5.

FIG. 24 is a cross-sectional view of the semiconductor device according to the embodiment 5.

FIG. 25 is a cross-sectional view showing a state that the semiconductor device according to the embodiment 5 is mounted on a mounting substrate.

### DETAILED DESCRIPTION

In the following embodiments, when required for convenience, the description will be made by dividing into a plurality of sections or embodiments, but except when specifically stated, they are not independent of each other, and one is related to the modified example, detail, supplementary description, or the like of part or all of the other. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle. Furthermore, in the following embodiments, it is needless to say that the constituent elements (including element steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

Embodiments will be explained in detail on the basis of drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In the drawings used in the embodiments, hatching may be omitted even in the case of cross-sectional view in order to make the drawings easier to see. Also, even in the case of a plan view, hatching may be used to make the drawing easier to see.

### Embodiment 1

### <Structure of Semiconductor Device>

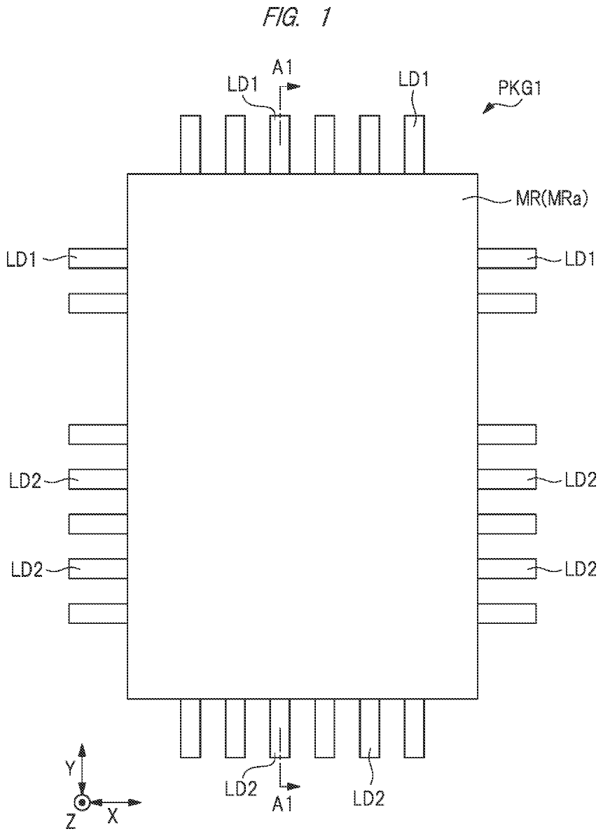

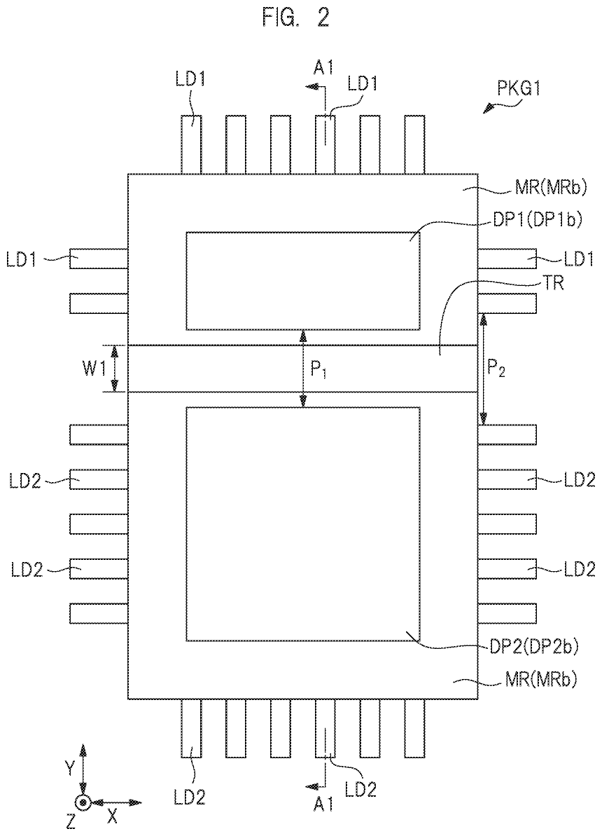

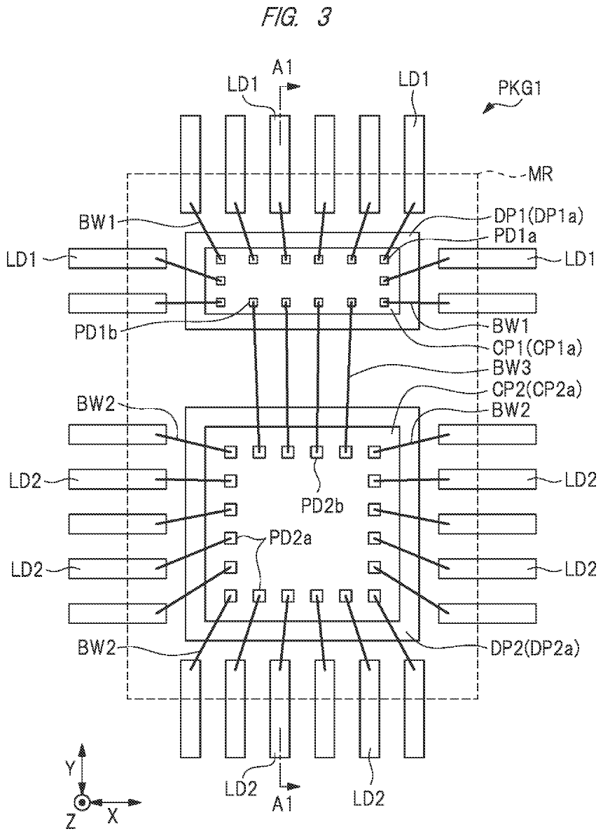

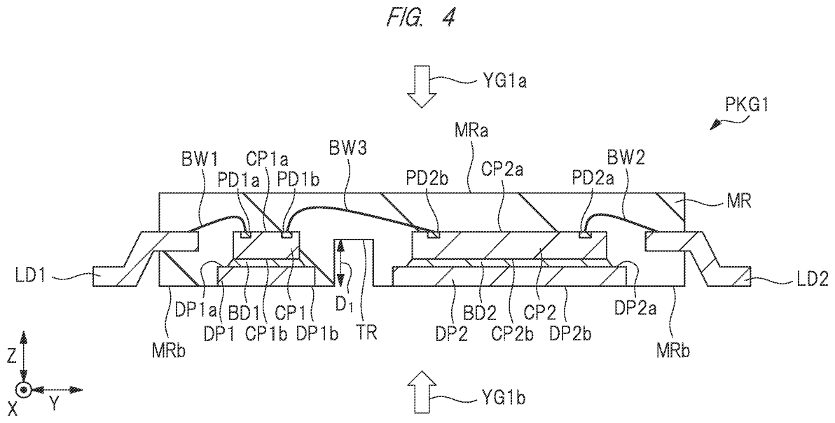

The construction of a semiconductor device PKG1 of the present embodiment will be described by referring to FIGS. 1 to 4. FIG. 1 and FIG. 2 are a plan view of the semiconductor device PKG1 according to the present embodiment, FIG. 3 is a perspective plan view of the semiconductor device PKG1 according to the present embodiment, and FIG. 4 is a cross-sectional view of the semiconductor device PKG1 according to the present embodiment.

It should be noted that FIG. 4 corresponds to a cross section at the position of A1-A1 line in FIGS. 1 to 3. In addition,

FIG. 1 corresponds to plan view (upper surface diagram) of the semiconductor device PKG1 when viewed from YGla of the arrow in FIG. 4. FIG. 2 corresponds to plan view (bottom view) of the semiconductor device PKG1 when the semiconductor device PKG1 is viewed from the arrow YGlb in FIG. 4. Further, FIG. 3 corresponds to a plan perspective view of the semiconductor device PKG1 when viewed from YGla of the arrow in FIG. 4 and the sealing portion MR is seen through.

The semiconductor device PKG1 shown in FIGS. 1 to 4 is a semiconductor package including a semiconductor chip CP1 and a semiconductor chip CP2 for controlling the semiconductor chip CP1.

The semiconductor device PKG1 includes a die pad (chip mounting portion) DP1, DP2, a semiconductor chip CP1 mounted on the die pad DP1, a semiconductor chip CP2 mounted on the die pad DP2, a plurality of leads (lead portions) LD1, LD2, a plurality of bonding wires (hereinafter simply referred to as wires) BW1, BW2, BW3, and a sealing portion (sealing resin portion, sealing member) MR for sealing them.

The sealing portion MR is made of, for example, a resin material such as a thermosetting resin material, and may include fillers and the like. For example, the sealing portion MR can be formed using a filler-containing epoxy-resin or the like.

The die pad DP1, DP2 and the lead LD1, LD2 are made of an electrical conductor, and are preferably made of a metallic material such as copper (Cu) or a copper alloy. The die pad DP1, DP2 and the lead LD1, LD2 are preferably formed of the same material (the same metallic material) as each other, and thus it is easy to manufacture a lead frame in which the die pad DP1, DP2 and the lead LD1, LD2 are connected to each other, and thus it is easy to manufacture the semiconductor device PKG1 using the lead frame.

A part of the lead LD1, LD2 is sealed in the sealing portion MR, and the other part protrudes from the side surface of the sealing portion MR to the outside of the sealing portion MR. Hereinafter, a portion of each lead LD1, LD2 located in the sealing portion MR is referred to as an inner lead portion, and a portion of each lead LD1, LD2 located outside the sealing portion MR is referred to as an outer lead portion.

Note that the semiconductor device PKG1 of the present embodiment has a configuration in which a part (outer lead portion) of each lead LD1, LD2 protrudes from the side surface of the sealing portion MR, and will be described below based on this structure, but the structure is not limited to this structure, and for example, a structure in which each lead LD1, LD2 hardly protrudes from the side surface of the sealing portion MR and a part of each lead LD is exposed on the lower surface of the sealing portion MR may be adopted.

The semiconductor chip CP1 has a front surface CPla and a rear surface CP1b, which are main surfaces opposite to each other. A plurality of pad electrodes (hereinafter, simply referred to as “pads”) PD1a, PD1b are formed on the front CPla of the semiconductor chip CP1. The semiconductor chip CP2 has a front surface CP2a and a rear surface CP2b, which are main surfaces opposite to each other. A plurality of pad electrodes (hereinafter, simply referred to as “pads”) PD2a, PD2b are formed on the front CP2a of the semiconductor chip CP2.

The die pad DP1 is a chip mounting portion for mounting the semiconductor chip CP1. The die pad DP1 has a chip mounting surface DPla, which is a main surface on the side on which the semiconductor chip CP1 is mounted, and a back surface DP1b, which is an opposing main surface. The semiconductor chip CP1 is mounted on the chip mounting surface DPla of the die pad DP1 via a bonding material BD1 such that the back surface CP1b of the semiconductor chip CP1 faces the chip mounting surface DPla of the die pad DP1. That is, the back surface CP1b of the semiconductor chip CP1 is bonded to the chip mounting surface DP1a of the die pad DP1 via the bonding material BD1.

The die pad DP2 is a chip mounting portion for mounting the semiconductor chip CP2. The die pad DP2 has a chip mounting surface DP2a, which is a main surface on the side on which the semiconductor chip CP2 is mounted, and a back surface DP2b, which is an opposing main surface. The semiconductor chip CP2 is mounted on the chip mounting surface DP2a of the die pad DP2 via a bonding material BD2 such that the back surface CP2b of the semiconductor chip CP2 faces the chip mounting surface DP2a of the die pad DP2. That is, the back surface CP2b of the semiconductor chip CP2 is bonded to the chip mounting surface DP2a of the die pad DP2 via the bonding material BD2. Each of the bonding material BD1, BD2 is made of a conductive bonding material such as solder or silver paste.

The semiconductor device PKG1 includes a plurality of leads LD1, a plurality of leads LD2, a plurality of wires BW1, a plurality of wires BW2, and a plurality of wires BW3. The semiconductor chip CP1 includes a plurality of pads PD1a and a plurality of pads PD1b. The semiconductor chip CP2 includes a plurality of pads PD2a and a plurality of pads PD2b.

A plurality of pads PD1a of the semiconductor chip CP1 and a plurality of leads LD1 are electrically connected to each other via a plurality of wires BW1. That is, one end portion of both ends of each wire BW1 is connected to each pad PD1a of the semiconductor chip CP1, and the other end portion is connected to the inner lead portion of each lead LD1. A plurality of pads PD2a of the semiconductor chip CP2 and a plurality of leads LD2 are electrically connected to each other via a plurality of wires BW2. That is, one end portion of both ends of each wire BW2 is connected to each pad PD2a of the semiconductor chip CP2, and the other end portion is connected to the inner lead portion of each lead LD2. A plurality of pads PD1b of the semiconductor chip CP1 and a plurality of pads PD2b of the semiconductor chip CP2 are electrically connected to each other via a plurality of wires BW3. That is, one end of both ends of each wire BW3 is connected to each pad PD1b of the semiconductor chip CP1, and the other end thereof is connected to each pad PD2b of the semiconductor chip CP2. The respective wire BW1, BW2, BW3 are electrically conductive, in particular made of metallic material, for example gold wire.

The planar shape of the sealing portion MR is substantially rectangular, and has four sides, and in the cases of FIGS. 1 to 3, has two sides substantially parallel to the X direction and two sides substantially parallel to the Y direction.

Here, the X direction and the Y direction are directions intersecting with each other, and more specifically, directions orthogonal to each other. In addition, the Z direction is a direction perpendicular to the X direction and the Y direction, and therefore is a thickness direction of the sealing portion MR.

The sealing portion MR has a principal surface MRa and a principal surface MRb which are located opposite to each other. That is, the sealing portion MR has a main surface MRa, a main surface MRb opposite to the main surface MRa, and four side surfaces (specifically, two side surfaces substantially parallel to the X direction and two side surfaces substantially parallel to the Y direction) connecting the main surface MRa and the main surface MRb. The main surface MRa, MRb is substantially parallel to the X direction and the Y direction, and the Z direction is substantially perpendicular to the main surface MRa, MRb.

In the present embodiment, the sealing portion MR has a main surface MRa of upper surface, and the sealing portion MR has a main surface MRb of a lower surface. Therefore, when the semiconductor device PKG1 is mounted on a mounting substrate (corresponding to a mounting substrate PB1 to be described later) or the like, the mounting substrate is mounted with the main surface MRb of the sealing portion MR serving as a mounting surface and the main surface MRb of the sealing portion MR facing the mounting substrate.

The semiconductor chip CP1, CP2 and the plurality of wires BW1, BW2, BW3 are sealed in the sealing portion MR and are not exposed from the sealing portion MR. On the other hand, the die pad DP1, DP2 except the back surface DP1b, DP2b is sealed in the sealing portion MR and is not exposed from the sealing portion MR, but the back surface DP1 of the die pad DP1 and the back surface DP2b of the die pad DP2 are exposed from the main surface MRb of the sealing portion MR. In the main surface MRb of the sealing portion MR, the back surface DP1b, which is an exposed portion of the die pad DP1, and the back surface DP2b, which is an exposed portion of the die pad DP2, are spaced apart from each other by a predetermined distance in the Y-direction.

On the main surface MRb of the sealing portion MR, between the exposed portion (back surface DP1b) of the die pad DP1 and the exposed portion (back surface DP2b) of the die pad DP2, a groove portion (concave portion, recessed portion) TR of the sealing portion is formed. Specifically, in the main surface MRb of the sealing portion MR, the groove portion TR is formed along the X-direction so as to cross the region between the exposed portion (back surface DP1b) of the die pad DP1 and the exposed portion (back surface DP2b) of the die pad DP2. The main surface MRb of the sealing portion MR is a substantially flat surface except for the groove portion TR, but is locally recessed in the groove portion TR. The groove portion TR includes a bottom surface and both side walls (both side surfaces), and both side walls are substantially parallel to the X-direction.

The outer lead portions of the respective lead LD1, LD2 protrude from the side surface of the sealing portion MR to the outside of the sealing portion MR. The outer lead portions of the respective lead LD1, LD2 are bent toward the main surface MRb of the sealing portion. Specifically, the outer lead portions of the respective lead LD1, LD2 are bent so that the lower surface near the end portion of the outer lead portion is located on substantially the same plane as the lower surface (in this case, the main surface MRb) of the sealing portion MR. The outer lead portion of the lead LD1, LD2 functions as an external connecting terminal portion (external terminal) of the semiconductor device PKG1.

In a plan view, the die pad DP1 and the die pad DP2 face each other in the Y direction (adjacent to each other in the Y direction). However, the die pad DP1 and the die pad DP2 are not in contact with each other and are spaced apart from each other by a predetermined distance, and a part of the sealing portion MR is interposed between the die pad DP1 and the die pad DP2. Note that the plan view corresponds to a plan view when viewed in a plane substantially parallel to the main surface MRa of the sealing portion MR, the chip mounting surface DP1a of the die pad DP1, the chip mounting surface DP2a of the die pad DP2, the surface of the semiconductor chip CP1, or the surface of the semiconductor chip CP2.

Each of the planar shapes of the semiconductor chip CP1, CP2 is substantially rectangular and has four sides, and in FIG. 3, has two sides substantially parallel to the X-direction and two sides substantially parallel to the Y-direction. Further, each of the planar shapes of the die pad DP1, DP2 is substantially rectangular and has four sides, and in FIG. 3, it has two sides substantially parallel to the X-direction and two sides substantially parallel to the Y-direction.

The planar dimension (planar area) of the semiconductor chip CP1 is smaller than the planar dimension (planar area) of the die pad DP1, and the semiconductor chip CP1 is included in the chip mounting surface DP1a of the die pad DP1 in plan view. Further, the planar dimension (planar area) of the semiconductor chip CP2 is smaller than the planar dimension (planar area) of the die pad DP2, and the semiconductor chip CP2 is included in the chip mounting surface DP2a of the die pad DP2 in plan view.

The height position of the die pad DP1 and the height position of the die pad DP2 are the same as each other. Therefore, the height position of the die pad DP1 on the chip mounting surface DP1a and the height position of the die pad DP2 on the chip mounting surface DP2a are the same as each other. In addition, the height position of the back surface DP1b of the die pad DP1 and the height position of the back surface DP2b of the die pad DP2 are the same as each other. The thickness of the die pad DP1 and the thickness of the die pad DP2 are the same as each other.

In the present application, when referring to the height position, the height position in the thickness direction of the sealing portion MR (Z direction), the side close to the main surface MRa of the sealing portion MR, the height is a high side, the side far from the main surface MRa of the sealing portion MR, the height is a low side.

Also, although the semiconductor device PKG of the present embodiment has a plurality of leads LD1 and a plurality of leads LD2, the distance P₂ between the lead LD1 and the lead LD2 along the outer surface of the sealing portion MR is larger than the distance P₁ between the die pad DP1 and the die pad DP2 (i.e., “P₂>P₁”). Here, the outer surface of the sealing portion MR is comprised of the main surface MRa and the main surface MRb of the sealing portion MR, and the side surface (four side surfaces when the planar shape of the sealing portion is rectangular) of the sealing portion MR. The distance P₁ between the die pad DP1 and the die pad DP2 corresponds to a distance in a plan view. For example, when the die pad DP1 and the die pad DP2 are spaced apart from each other in the Y direction and are adjacent to each other, the distance P₁ corresponds to the distance between the die pad DP1 and the die pad DP2 in the Y direction. Further, the closest distance P₂ between the lead LD1 and the lead LD2 along the outer surface of the sealing portion MR corresponds to the distance (creepage distance) between the lead LD1 and the lead LD2, which are closest to each other in the plurality of leads LD1, LD2 included in the semiconductor device PKG. In case of FIG. 2, the distance between the lead LD1 and the lead LD2 arranged next to each other in the Y-direction along the side surface of the sealing portion MR is the nearest distance P₂.

The first power (power for driving the circuitry in the semiconductor chip CP1) is supplied to the semiconductor chip CP1 in the semiconductor device PKG1 via the lead LD1 and the wire BW1. A second power (power for driving the circuitry in the semiconductor chip CP2) high than the first power is supplied to the semiconductor chip CP2 of the semiconductor device PKG1 via the lead LD2 and the wire BW2. A signal (control signal) for controlling the semiconductor chip CP2 (circuit in the semiconductor chip CP2) is supplied from the semiconductor chip CP1 in the semiconductor device PKG1 to the semiconductor chip CP2 via the wire BW3.

### <Manufacturing Step of Semiconductor Device PKG1>

An exemplary manufacturing step of the semiconductor device PKG1 of the present embodiment will be described.

First, a lead frame having a lead LD1, LD2 and a die pad DP1, DP2 and a semiconductor chip CP1, CP2 are prepared. The semiconductor chip CP1, CP2 may be prepared first, the lead frame may be prepared first, or the semiconductor chip CP1, CP2 and the lead frame may be prepared together.

Next, a die bonding step is performed. Accordingly, the semiconductor chip CP1 is mounted on the die pad DP1 via the bonding material BD1 and bonded, and the semiconductor chip CP2 is mounted on the die pad DP2 via the bonding material BD2 and bonded. At this time, the semiconductor chip CP1 is mounted on the chip mounting surface DP1a of the die pad DP1 via the bonding material BD1 so that the back surface CP1b of the semiconductor chip DP1 faces the chip mounting surface DP1a of the die pad. Further, the semiconductor chip CP2 is mounted on the chip mounting surface DP2a of the die pad DP2 via the bonding material BD2 so that the back surface CP2b of the semiconductor chip DP2 faces the chip mounting surface DP2a of the die pad.

Next, a wire bonding step is performed. As a result, the plurality of pads PD1a of the semiconductor chip CP1 and the plurality of leads LD1 are electrically connected to each other via the plurality of wires BW1. Further, the plurality of pads PD2a of the semiconductor chip CP2 and the plurality of leads LD2 are electrically connected to each other via the plurality of wires BW2. Further, the plurality of pads PD1b of the semiconductor chip CP1 and the plurality of pads PD2b of the semiconductor chip CP2 are electrically connected to each other via the plurality of wires BW3.

Next, a molding step is performed to form a sealing portion MR. At this time, a portion corresponding to the groove TR is provided in the mold for forming the sealing part MR, so that the sealing part MR has the groove TR at the stage when the sealing part MR is formed. Alternatively, it is also possible to form the groove TR on the sealing portion MR by grinding such as dicing after forming the sealing portion MR having no groove TR in the molding step. The former (contrivance of the mold) can simplify the manufacturing step.

Next, the lead LD1, LD2 is cut from the frame of the lead frame.

Next, the lead LD1, LD2 is bent.

In this way, the semiconductor device PKG1 of present embodiment can be produced.

### <Mounting Structure of Semiconductor Device>

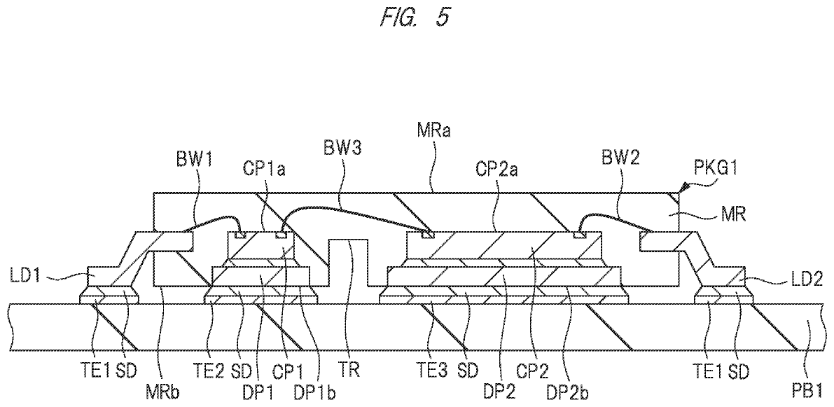

FIG. 5 is a cross-sectional view showing a state that the semiconductor device PKG1 according to the present embodiment is mounted on a mounting substrate (wire substrate) PB1. The cross section of the semiconductor device PKG1 shown in FIG. 5 corresponds to the cross section of the above FIG. 4.

The semiconductor device PKG1 is mounted on the mounting substrate PB1 such that the main surface MRb of the sealing portion MR faces the mounting substrate PB1. Each of the lead LD1, LD2 of the semiconductor device PKG1 is electrically connected to and fixed to the terminal TEL of the mounting substrate PB1 via a conductive bonding material such as a solder SD. In FIG. 5, the exposed portion (back surface DP1b) of the die pad DP1 from the main surface MRb of the sealing portion MR and the exposed portion (back surface DP2b) of the die pad DP2 are respectively connected to the terminal TE2, TE3 of the mounting substrate PB1 via a conductive bonding material such as a solder SD. In this case, heat generated in the semiconductor chip CP1 is conducted through the bonding material BD1, the die pad DP1, and the solder SD to the mounting substrate PB1 to be dissipated, and heat generated in the semiconductor chip CP2 is conducted to the mounting substrate PB1 through the bonding material BD2, the die pad DP2, and the solder SD to be dissipated. In the mounting substrate PB1, a terminal TE2, TE3 for connecting the die pad DP1, DP2 may not be provided.

### <History of Study>

The present inventors have studied a configuration in which a semiconductor chip requiring high breakdown voltage (a high breakdown voltage chip, for example, a semiconductor chip on which a IGBT is formed) and a semiconductor chip that controls the high breakdown voltage chip and does not require high breakdown voltage (a low breakdown voltage chip, for example, a control IC chip) are mounted in one semiconductor device. Specifically, a die pad (high breakdown voltage die pad) on which a high breakdown voltage chip is mounted and a die pad (low breakdown voltage die pad) on which a low breakdown voltage chip is mounted are provided, respectively, and in consideration of the heat dissipation property of the high breakdown voltage chip that is likely to generate heat, it is studied to expose the two die pads (at least high breakdown voltage die pad) from the sealing body. The semiconductor chip CP1 corresponds to a high breakdown voltage chip, and the semiconductor chip CP2 corresponds to a low breakdown voltage chip.

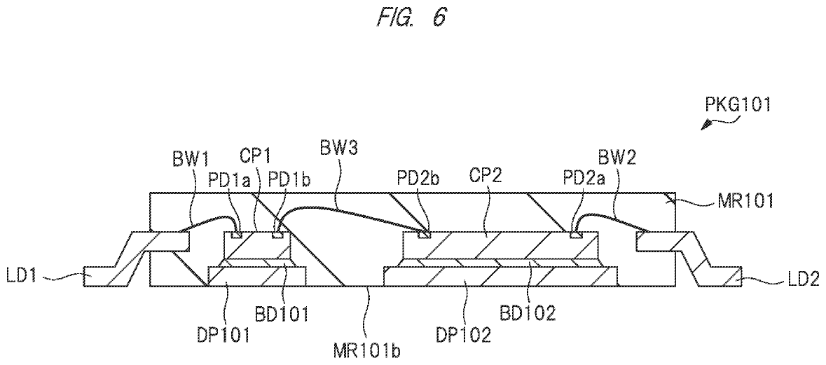

FIG. 6 is a cross-sectional view of a semiconductor device PKG101 of the examined example 1 studied by the present inventor, and shows a cross section corresponding to the above FIG. 4.

The semiconductor device PKG101 of the examined example 1 shown in FIG. 6 has a die pad DP101, DP102, a semiconductor chip DP101 mounted via a bonding material BD101 on the die pad BW1, a semiconductor chip CP2 mounted via a bonding material BD2 on the die pad DP102, a plurality of leads BW1, BW2, BW3, and a sealing portion MR101 for sealing these. A plurality of pads PD1a and a plurality of leads LD1 of the semiconductor chip CP1 are electrically connected to each other via a plurality of wires BW1, and a plurality of pads PD2a and a plurality of leads LD2 of the semiconductor chip CP2 are electrically connected to each other via a plurality of wires BW2. Further, a plurality of pads PD1b of the semiconductor chip CP1 and a plurality of pads PD2b of the semiconductor chip CP2 are electrically connected to each other via a plurality of wires BW3. Each die pad DP101, DP102 is sealed in the sealing portion MR101 except the back surface, but the back surface of each the die pad DP101, DP102 is exposed from the main surface MR101b which is the lower surface of the sealing portion MR101.

According to studies by the present inventors, in the semiconductor device PKG101 of the examined example 1 shown in FIG. 6, it has been found that a discharge may occur between the back surface of the die pad DP101 exposed from the main surface MR101b of the sealing portion MR101 and the back surface of the die pad DP102. When a discharge occurs between the die pad DP101 and the die pad DP102 exposed from the main surface MR101b of the sealing portion MR101, a leakage current is generated between the die pad DP101 and the die pad DP102, which may lead to a decrease in the performance of the electronic device having the semiconductor device PKG101. Therefore, it is desirable to prevent a discharge from occurring between the die pad DP101 and the die pad DP102 exposed from the main surface MR101b of the sealing portion MR101.

Here, the power supplied to the semiconductor chip CP2 to drive the circuit in the semiconductor chip CP2 is higher (larger) than the power supplied to the semiconductor chip CP1 to drive the circuit in the semiconductor chip CP1. That is, the semiconductor chip CP2 is supplied with power high than the power supplied to the semiconductor chip CP1. Reflecting this, a higher potential difference may be generated between the die pad DP101 on which the semiconductor chip CP1 is mounted and the die pad DP102 on which the semiconductor chip CP2 is mounted. When the high-potential difference is generated, discharge (corona discharge, creeping discharge) may occur along the front surface (main surface MR101b) of the sealing portion MR101 between the back surface of the die pad DP101 exposed from the main surface MR101b of the sealing portion and the back surface of the die pad DP102.

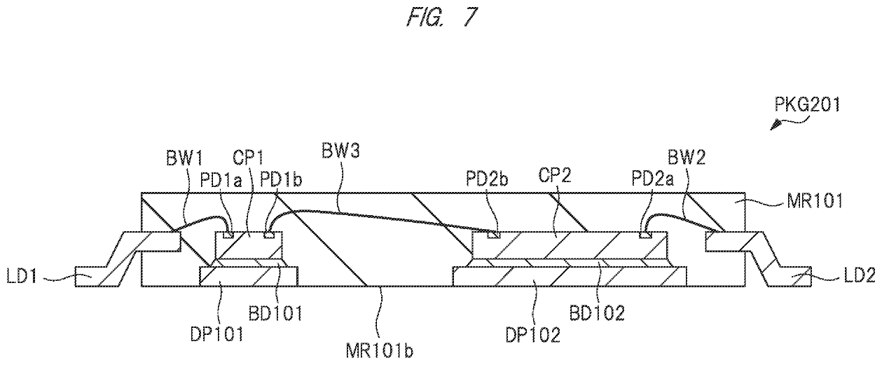

FIG. 7 is a cross-sectional view of a semiconductor device PKG201 of the examined example 2 studied by the present inventor, and shows a cross section corresponding to the above FIGS. 4 and 6.

For the semiconductor device PKG201 of the examined example 2 shown in FIG. 7, the back surface of the die pad DP101 and the back surface of the die pad DP102 are exposed from the lower surface of the sealing portion MR101 (main surface MR101b), but the distance between the die pad DP101 and the die pad DP102 is larger than that of the semiconductor device PKG101 of the examined example 1 shown in FIG. 6.

For the semiconductor device PKG201 of the examined example 2 shown in FIG. 7, compared to the semiconductor device PKG101 of the examined example 1 shown in FIG. 6, by increasing the distance between the die pad DP101 and the die pad DP102, the distance between the back surface of the die pad DP101 and the back surface of the die pad MR101 exposed from the main surface MR101b of the sealing portion is also increased. Consequently, compared to the semiconductor device PKG101 of the examined example 1 shown in FIG. 6, the semiconductor device PKG201 of the examined example 2 shown in FIG. 7 is less likely to be discharged between the back surface of the die pad DP101 exposed from the main surface MR101b of the sealing portion MR101 and the back surface of the die pad DP102.

However, in the semiconductor device PKG201 of the examined example 2 shown in FIG. 7, the planar dimension (planar area) of the semiconductor device PKG201 increases, which leads to an increase in the size of the semiconductor device PKG201, reflecting the fact that the distance between the die pad DP101, DP102 is increased.

In addition, in the semiconductor device PKG201 of the examined example 2 shown in FIG. 7, the distance between the semiconductor chips CP1, CP2 mounted on the die pad DP101, DP102 is also increased, reflecting that the distance between the die pads DP101, DP102 is increased, and consequently, the lengths of the plurality of wires BW3 connecting the plurality of pads of the semiconductor chip CP1 and the plurality of pads of the semiconductor chip CP2, respectively, are increased. When the length of the wire BW3 is increased, the plurality of wires BW3 are easily contacted with each other by pushing the plurality of wires MR101 of the resin-material for forming the sealing portion when the sealing portion MR101 is formed in the molding step. This leads to a reduction in the production yield of the semiconductor device PKG201 to be produced. Therefore, it is not advisable to increase the distance between the die pad DP101 and the die pad DP102 as in the semiconductor device PKG201 of the examined example 2 shown in FIG. 7.

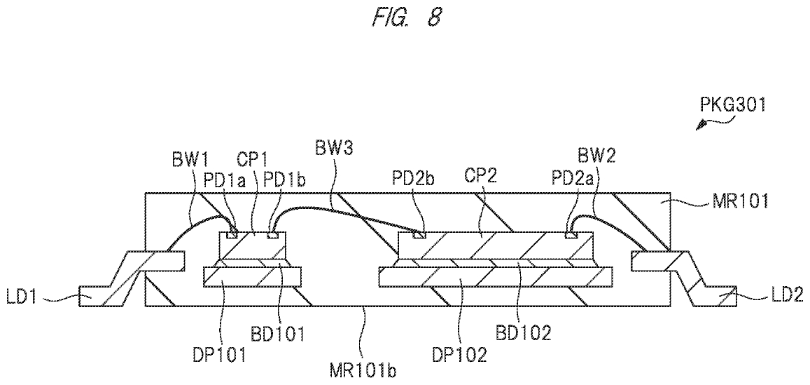

FIG. 8 is a cross-sectional view of a semiconductor device PKG301 of the examined example 3 studied by the present inventor, and shows a cross section corresponding to the above FIGS. 4, 6 and 7.

In the semiconductor device PKG301 of the examined example 3 shown in FIG. 8, the die pad DP101 and the die pad DP102 are not exposed from the lower surface (main surface MR101b) of the sealing portion MR101, and the back surface of each of the die pad DP101, DP102 is covered with the sealing portion MR101.

In the semiconductor device PKG301 of the examined example 3 shown in FIG. 8, since the die pad DP101, DP102 is not exposed from the sealing portion MR, even if a high-potential difference occurs between the die pad DP101 on which the semiconductor chip CP1 is mounted and the die pad DP102 on which the semiconductor chip CP2 is mounted, no discharge occurs between the die pad DP101 and the die pad DP102.

However, in the semiconductor device PKG301 of the examined example 3 shown in FIG. 8, since the die pad DP101, DP102 is not exposed from the sealing portion MR101, it is difficult to discharge the heat generated in CP1, CP2 of the semiconductor chip to the outside of the semiconductor device PKG301 from the die pad DP101, DP102. In particular, since the semiconductor chip CP2 generates a larger amount of heat than the semiconductor chip CP1, the temperature of the semiconductor chip CP2 and the die pad DP102 on which the semiconductor chip is mounted increases with the generation of heat of the semiconductor chip CP2, but since the die pad DP102 is not exposed from the sealing portion MR101 having a lower thermal conductivity, it is difficult to conduct the heat of the die pad DP102 to the outside of the semiconductor device PKG301. As a consequence, the performance of the semiconductor device PKG301 may deteriorate due to an increase in the temperature of the semiconductor chip CP1, CP2 (particularly, the semiconductor chip CP2) when the semiconductor device PKG301 is operated.

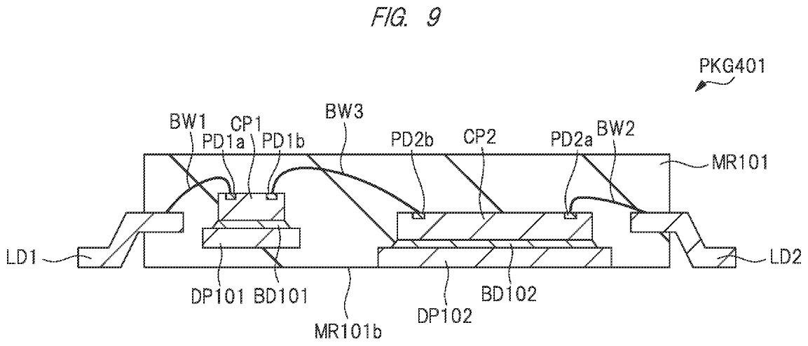

FIG. 9 is a cross-sectional view of a semiconductor device PKG401 of the examined example 4 studied by the present inventor, and shows a cross section corresponding to the above FIGS. 4 and 6 to 8.

In case of the semiconductor device PKG401 of the examined example 4 shown in FIG. 9, the height positions of the die pad DP101 and the die pad DP102 are different from each other, and the height position of the die pad DP101 is higher than the height position of the die pad DP102. Then, the die pad DP101 is not exposed from the sealing portion MR101 by using the difference in height between the die pad DP101 and the die pad DP102, but the back surface of the die pad DP102 is exposed from the lower surface (main surface MR101b) of the sealing portion MR101.

In the semiconductor device PKG401 of the examined example 4 shown in FIG. 9, one of the die pad DP101, DP102 (die pad DP101) is not exposed from the sealing portion MR101. Therefore, even if a high-potential difference is generated between the die pad DP101 on which the semiconductor chip CP1 is mounted and the die pad CP2 on which the semiconductor chip DP102 is mounted, no discharge is generated between the die pad DP101 and the die pad DP102. In addition, in examined example 4 semiconductor device PKG401 shown in FIG. 9, the back surface of the semiconductor chip CP1 mounting the semiconductor chip CP2 having a larger heat generation value than the semiconductor chip DP102 is exposed from the main surface MR101b of the sealing portion MR101, so that the heat generated in the semiconductor chip CP2 is easily emitted to the outside of the semiconductor device PKG401 from the die pad DP102.

However, in the semiconductor device PKG401 of the examined example 4 shown in FIG. 9, since the height positions of the die pad DP101 and the die pad DP102 differ, it is difficult to perform the wire bonding step at the time of manufacturing. That is, in the wire bonding step, the wire DP101, DP102 needs to be connected to the pad of the semiconductor chip CP1, CP2 mounted on the die pad BW1, BW2, BW3 while supporting the die pad DP101, DP102, but it becomes difficult to support the die pad when the height positions of the die pad DP101 and the die pad DP102 differ. For this reason, in the semiconductor device PKG401 of the examined example 4 shown in FIG. 9, it is difficult to control the process of the wire bonding step at the time of manufacturing, which may lead to a decrease in manufacturing yield and an increase in manufacturing costs.

### <Key Features and Effects>

The semiconductor device PKG of the present embodiment includes a semiconductor chip CP1, CP2, a die pad DP1, DP2 for mounting the semiconductor chip CP1, CP2, a plurality of lead portions LD1, LD2, a plurality of wires BW1, BW2, BW3, and a sealing portion MR for sealing them. The semiconductor chip CP1 is mounted on the chip mounting surface DP1a of the die pad DP1 via a bonding material BD1, and the semiconductor chip CP2 is mounted on the chip mounting surface DP2a of the die pad DP2 via a bonding material BD2. The plurality of pads PD1a of the semiconductor chip CP1 and the plurality of lead portions LD1 are electrically connected to each other via a plurality of wires BW1, and the plurality of pads PD2a of the semiconductor chip CP2 and the plurality of lead portions LD2 are electrically connected to each other via a plurality of wires BW2. The plurality of pads PD1b of the semiconductor chip CP1 and the plurality of pads PD2b of the semiconductor chip CP2 are electrically connected to each other via the plurality of wires BW3.

One of the main features of present embodiment is that, from the main surface MRb of the sealing portion MR, the back surface DP1b of the die pad DP1 and the back surface DP2b of the die pad DP2 are respectively exposed, and the groove portion TR of the sealing portion MR is formed between the back surface DP1b of the die pad DP1 and the back surface DP2b of the die pad DP2 in the main surface MRb of the sealing portion MR. In the main surface MRb of the sealing portion MR, the groove portion TR is formed so as to cross a region between the back surface DP1b of the die pad DP1 and the back surface DP2b of the die pad DP2.

In the present embodiment, since the sealing portion MR has the main surface MRb exposed to each back surface DP1, DP2 of the die pad DP1b, DP2b, heat generated in CP1, CP2 of the semiconductor chip is easily released from the die pad to the outside of the semiconductor device PKG1. In particular, the semiconductor chip CP2 has a larger heat generation value than the semiconductor chip CP1 because the semiconductor chip CP2 is supplied with a larger power than the power supplied to the semiconductor chip CP1. Therefore, the temperature of the semiconductor chip CP2 and the die pad DP2 on which the semiconductor chip is mounted increases with the heat generation of the semiconductor chip CP2, but the die pad DP2 is exposed from the sealing portion MR having a lower thermal conductivity, so that the heat of the die pad DP2 is easily conducted to the outside of the semiconductor device PKG1. As a consequence, the performance of the semiconductor device PKG1 can be improved because the temperature increasing of the semiconductor chip CP1, CP2 (in particular, the semiconductor chip CP2) when the semiconductor device PKG1 is operated can be suppressed.

Further, in the present embodiment, in the main surface MRb of the sealing portion MR, it is possible to suppress or prevent the occurrence of a discharge between the back surface DP1b of the die pad DP1, which is exposed from the sealing portion MR at the main surface MRb of the sealing portion MR, and the back surface DP2b of the die pad DP2, which is exposed from the sealing portion MR at the main surface MRb of the sealing portion MR, by forming the groove TR in the sealing portion MR between the back surface DP1b of the die pad DP1 and the back surface DP2b of the die pad DP2. The reason for this will be described below.

In the semiconductor device PKG101 of the examined example 1 shown in FIG. 6, when the discharge occurs between the back surface of the die pad DP101 and the back surface of the die pad DP102 exposed from the main surface MR101b of the sealing portion MR101, the discharge occurs along the front surface of the sealing portion MR101 located between the back surface of the die pad DP101 and the back surface of the die pad DP102. Therefore, in the main surface MR101b of the sealing portion MR101, as the creepage distance between the exposed portion of the die pad DP101 and the exposed portion of the die pad DP102 is increased, a discharge is less likely to occur between the exposed portion of the die pad DP101 and the exposed portion of the die pad DP102. Here, the creepage distance corresponds to a distance along the surface of the sealing portion MR101 interposed between the die pad DP101, DP102. In the examined example 2 of the semiconductor device PKG101 shown in FIG. 6, the semiconductor device PKG201 of the examined example 2 shown in FIG. 7 has a larger creepage distance between the exposed portion of the die pad DP101 and the exposed portion of the die pad DP102 in the main surface MR101b of the sealing portion MR101, and consequently is less likely to be discharged between the exposed portion of the die pad DP101 and the exposed portion of the die pad DP102. However, in the semiconductor device PKG201 of the examined example 2 shown in FIG. 7, the planar dimension of the semiconductor device PKG201 is increased due to the increased spacing between the die pad DP101, DP102, and the wire BW3 easily come into contact with each other when the sealing portion MR101 is formed.

On the other hand, in the semiconductor device PKG1 of present embodiment, the creepage distance between the exposed portion (back surface DP1b) of the die pad DP1 and the exposed portion (back surface DP2b) of the die pad DP2 in the main surface MRb of the sealing portion MR is increased by the presence of the trench TR. Here, the creepage distance corresponds to a distance along the surface of the sealing portion MR interposed between the die pad DP1, DP2.

In the semiconductor device PKG of present embodiment, the creepage distance between the exposed portion (back surface DP1b) of the die pad DP1 and the exposed portion (back surface DP2b) of the die pad DP2 at the main surface MRb of the sealing portion MR is expressed as L₁. In the semiconductor device PKG101 of the examined example 1 shown in FIG. 6, the creepage distance between the exposed portion (back surface) of the die pad DP101 and the exposed portion (back surface) of the die pad DP102 at the main surface MR101b of the sealing portion MR101 is expressed as L₁₀₁. If the distance between the die pad DP1 and the die pad DP2 and the distance between the die pad DP101 and the die pad DP102 are the same as each other when comparing the semiconductor device PKG of the present embodiment with the semiconductor device PKG101 of the examined example 1 shown in FIG. 6, “L₁” is larger than “L₁₀₁” by twice the depth D1 of the trench TR, thus “L₁=L₁₀₁+D1×2” holds.

When a discharge occurs between the exposed portions of the die pad DP1, DP2 on the main surface MRb of the sealing portion MR, the length of the discharge path is approximately equal to the creepage distance L₁ between the exposed portions of the die pad DP1, DP2. Therefore, as the creepage distance L₁ increases, the length of the discharge path increases, and discharge is less likely to occur between the exposed portions of the die pad DP1, DP2. When the groove TR is formed, when the discharge occurs between the exposed portions (back surface DP1b, DP2b) of the die pad DP1, DP2 in the main surface MRb of the sealing portion MR, since the discharge path will include both side walls and the bottom surface of the groove TR, as compared with the case where the groove TR is not formed, the discharge path becomes longer, consequently, the exposed portions of the die pad DP1, DP2 (back surface DP1b, DP2b) discharge hardly occurs between. Therefore, as in the present embodiment, in the main surface MR of the sealing portion, in the main surface MRb of the sealing portion DP1b, DP2b, it is possible to suppress or prevent the occurrence of a discharge between exposed portions (back surface DP1, DP2) of the die pad DP1, DP2 on the main surface MR of the sealing portion MR by forming the groove portion TR of the sealing portion between exposed portions (back surface DP1b, DP2b) of the die pad OOG.

Further, in the present embodiment, since the groove TR is provided on the main surface MRb of the sealing portion MR, it is possible to increase the creepage distance between the exposed portions (back surface DP1b, DP2b) of the die pad DP1, DP2 on the main surface MRb of the sealing portion MR without increasing the distance between the die pad DP1, DP2. Therefore, the planar dimension (planar area) of the semiconductor device PKG1 can be suppressed. In addition, it is possible to prevent or prevent the wire BW3 from contacting each other when the sealing portion MR is formed.

Further, in the main surface MRb of the sealing portion MR, the groove portion TR is formed so as to cross a region between the back surface DP1b of the die pad DP1 and the back surface DP2b of the die pad DP2 (see FIG. 2). Specifically, in the main surface MRb of the sealing portion MR, the back surface DP1b of the die pad DP1 and the back surface DP2b of the die pad DP2 are separated in the Y direction, and the groove portion TR extends in the X direction so as to cross a region between the back surface DP1b of the die pad DP1 and the back surface DP2b of the die pad MRb. As a result, in the main surface MRb of the sealing portion MR, the groove portion TR crosses a straight line connecting an arbitrary position of the exposed portion of the die pad DP1 (here, the back surface DP1b) and an arbitrary position of the exposed portion of the die pad DP2 (here, the back surface DP2b). Therefore, since the dischargeable path between the exposed portions (back surface DP1b, DP2b) of the die pad DP1, DP2 in the main surface MRb of the sealing portion MR, the groove portion TR crosses, it is possible to accurately suppress or prevent the discharge between the exposed portions (back surface DP1b, DP2b) of the die pad DP1, DP2 in the main surface MRb of the sealing portion MR.

Further, in the main effect MRb of the sealing portion MR, the groove portion TR may not reach the side surface of the sealing portion DP1 because it is possible to suppress or prevent a discharge between the exposed portions (back surface DP1b, DP2b) of the die pad DP1, DP2 on the main surface MRb of the sealing portion MR as long as it crosses the region between the back surface DP1b of the die pad MR and the back surface DP2b of the die pad DP2. However, it is more preferable that the groove portion TR reaches both side surfaces (both side surfaces located on opposite sides) of the sealing portion MR, so that the groove portion TR of the sealing portion MR can be easily formed, and the discharge-suppressing effect can also be enhanced.

Further, as the depth D1 of the trench TR is increased, the creepage distance between the exposed portions (back surface DP1b, DP2b) of the die pad DP1, DP2 in the main surface MRb of the sealing portion MR is increased, so that a discharge is less likely to occur between the exposed portions (back surface DP1b, DP2b) of the die pad DP1, DP2. Therefore, the depth TR of the sealing portion MR in the groove D1 is preferably made deeper (larger) to some extent, and in this viewpoint, the depth D1 of the groove TR is preferably larger the respective thicknesses of the die pad DP1, DP2. That is, in the thickness direction (Z direction) of the sealing portion MR, the height position of the bottom surface of the trench TR is preferably higher than each of the chip mounting surface DP1a of the die pad DP1 and the chip mounting surface DP2a of the die pad DP2. Further, in the thickness direction (Z direction) of the sealing portion MR, it is more preferable that the height position of the bottom surface of the trench TR is higher than the central of the thickness of the semiconductor chip CP1, CP2.

On the other hand, if the groove TR is too deep, the groove TR may adversely affect the wire BW3. The wire BW3 connects the pad PD1b of the semiconductor chip CP1 and the pad PD2b of the semiconductor chip CP2, but it is possible to avoid the risk that the groove TR adversely affects the wire BW3 if the height position of the bottom surface of the groove TR is lower than the surface CPla of the semiconductor chip CP1 and the surface CP1 of the semiconductor chip. Therefore, the height position of the bottom surface of the trench TR is preferably lower than each of the surface CPla of the semiconductor chip CP1 and the surface CP2a of the semiconductor chip CP2.

Therefore, it is preferable that the height position of the bottom surface of the trench TR is higher than the respective chip mounting surface DP1a, DP2a of the die pad DP1, DP2 and lower than the respective front surface CPla, CP2a of the semiconductor chip CP1, CP2. Accordingly, it is possible to efficiently suppress or prevent a discharge between exposed portions (back surface DP1b, DP2b) of the die pad DP1, DP2 on the main surface MRb of the sealing portion MR while accurately preventing the forming of the trench TR from adversely affecting the wire BW3.

In addition, a discharge may occur beyond the groove TR if the width W1 of the groove TR (see FIG. 2) is too small. Therefore, it is preferable that W1 of the trench TR is increased to some extent. In this viewpoint, W1 of the trench TR is preferably equal to or greater than 1.5 mm. Accordingly, it is possible to accurately suppress or prevent a discharge from occurring beyond the trench TR.

In the semiconductor device PKG1 of the present embodiment, the height position of the die pad DP1 and the height position of the die pad DP2 are the same in the thickness direction (Z direction) of the sealing portion MR. Therefore, it is easy to perform the wire bonding step at the time of manufacturing the semiconductor device PKG1. That is, in the wire bonding step, although it is necessary to connect each wire BW1, BW2, BW3 with each pad of each semiconductor chip CP1, CP2 mounted on each die pad DP1, DP2 while each die pad DP1, DP2 is supported, it is easy to support each die pad DP1, DP2 because the height positions of each die pad DP1, DP2 are the same as each other. Therefore, the semiconductor device PKG1 of the present embodiment facilitates the process control of the wire bonding step at the time of manufacturing. In addition, the manufacturing yield of the semiconductor device PKG1 can be improved, and the manufacturing cost of the semiconductor device PKG1 can be suppressed.

Also, in the semiconductor device PKG1 of the present embodiment, the lead LD1 and the lead LD2 along the outer surface of the sealing portion MR have a closest distance P₂ larger than (i.e., “P₂>P₁”) a distance P₁ between the die pad DP1 and the die pad DP2. Unlike present embodiment, there is a concern that creeping discharge (discharge along the outer surface of the sealing portion MR) occurs between the adjacent lead LD1 and the lead LD2 when the closest distance LD1 and the lead LD2 along the outer surface of the sealing portion P₂ is smaller than the distance P₁ between the die pad DP1 and the die pad DP2 (that is, when the distance is “P₂<P₁”). In contrast, in present embodiment, creeping a discharge is less likely to occur between the lead LD1 and the lead MR because the lead LD1 and the lead LD2 closest distance P₂ along the outer surface of the sealing portion LD2 are larger than the distance P₂ between the die pad DP1 and the die pad DP2 (i.e., MR). With respect to the die pad DP1 and the die pad DP2 in which creeping discharge is feared, creeping discharge between the die pad DP1 and the die pad DP2 can be suppressed or prevented by providing the trench MR the sealing portion with the trench TR as described above. For this reason, present embodiment is particularly useful when the closest distance P₂ between the lead LD1 and the lead LD2 along the outer surface of the sealing portion MR is larger than the distance P₁ between the die pad DP1 and the die pad DP2 (i.e., in “P₂>P₁”), and the same applies to the following embodiments 2˜5.

### Embodiment 2

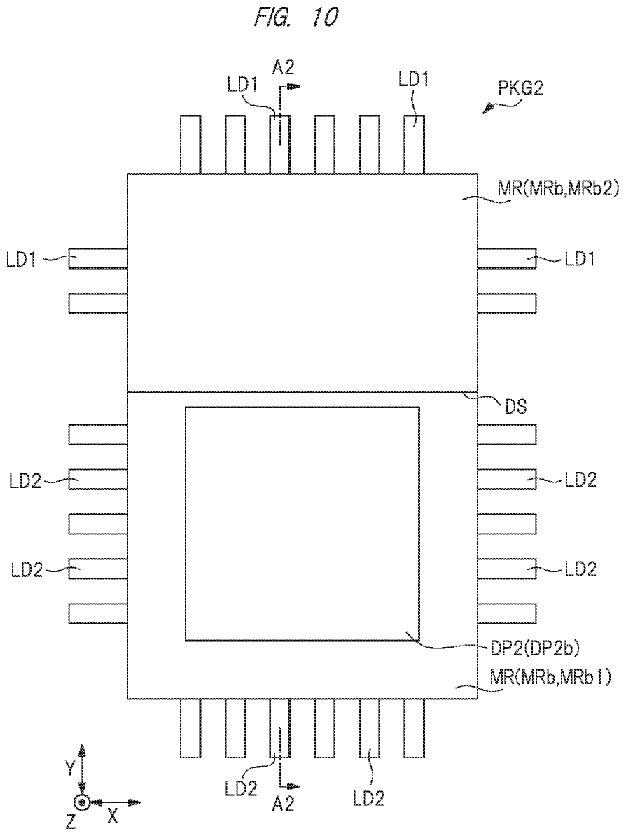

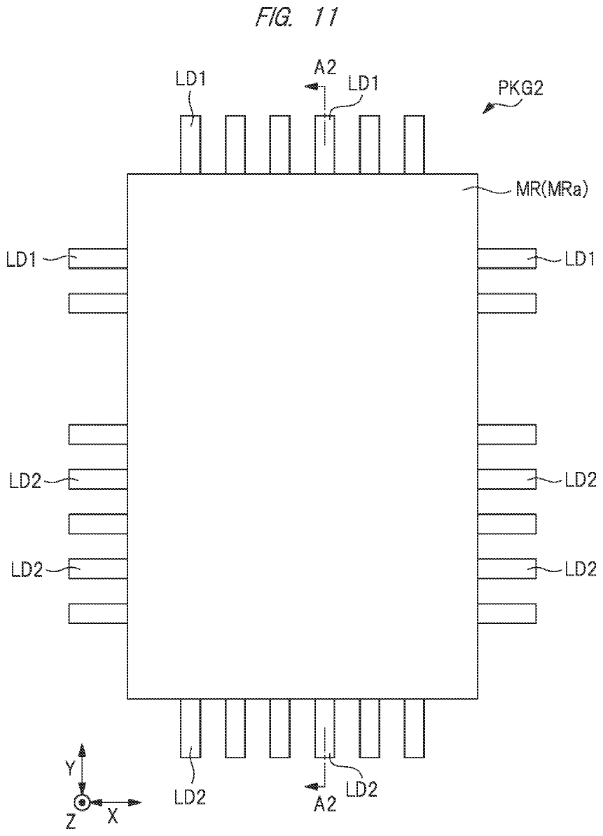

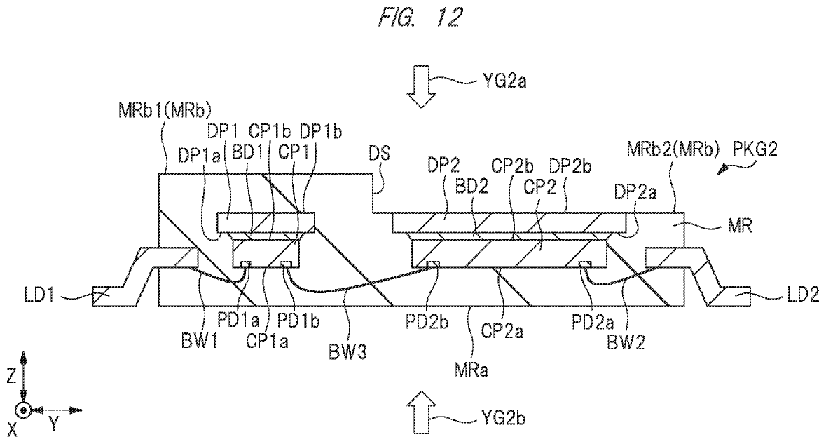

The construction of a semiconductor device PKG2 of the present embodiment 2 will be described by referring to FIG. 10 to FIG. 12. FIG. 10 and FIG. 11 are a plan view of the semiconductor device PKG2 according to the present embodiment 2, and FIG. 12 is cross-sectional view of the semiconductor device PKG2 according to the present embodiment 2. FIG. 12 corresponds to a cross section at the position of A2-A2 in FIGS. 10 and 11. FIG. 10 corresponds to the plan view (upper surface diagram) of the semiconductor device PKG2 when the semiconductor device PKG2 is viewed from the arrow YG2a in FIG. 12. FIG. 11 corresponds to the plan view (bottom view) of the semiconductor device PKG2 when the semiconductor device PKG2 is viewed from the arrow YG2b in FIG. 12. Further, when looking at the semiconductor device PKG2 from the arrow YG2b in FIG. 12, a perspective plan view of the semiconductor device PKG2 seen through the sealing portion MR is substantially the same as in the above FIG. 3, and therefore, the illustration thereof is omitted here.

The semiconductor device PKG2 according to the embodiment 2 will be described below with a focus on the difference between the semiconductor device PKG1 of the embodiment 1 and the semiconductor device PKG2 of the embodiment 2.

In the semiconductor device PKG2 of the present embodiment 2, the groove TR is not formed on the main surface MRb of the sealing portion MR. Instead, in the present embodiment 2, the sealing portion MR is formed on the main surface MRb of the sealing portion MR at a position between the die pad DP1 and the die pad DP2 in a plan view with a step DS. That is, the main surface MRb of the sealing portion MR is constituted by a flat surface MRb1, a flat surface MRb2, and a step (step surface) DS connecting them, and the step DS is located at the boundary between the flat surface MRb1 and the flat surface MRb2. The distance between the surface MRb2 and the main surface MRa of the sealing portion MR (that is, the thickness of the sealing portion MR in the surface MRb2) is larger than the distance between the surface MRb1 and the main surface MRa of the sealing portion MR (that is, the thickness of the sealing portion MR in the surface MRb1). Each of the surface MRb1, MRb2 is a flat surface substantially parallel to the X direction and the Y direction. As in the embodiment 1, in the present embodiment 2, the main surface MRa of the sealing portion MR is a flat surface (more specifically, a flat surface substantially parallel to the X direction and the Y direction).

In a plan view, the level difference DS of the sealing portion MR is formed so as to cross the region between the die pad DP1 and the die pad DP2. Specifically, in a plan view, the die pad DP1 and the die pad DP2 are spaced apart from each other in the Y direction, and the sealing portion MR has a step DS extending in the X direction so as to cross the region between the die pad DP1 and the die pad DP2. Therefore, the level difference DS is substantially parallel to the X-direction. In FIG. 12, the level difference DS reaches both side surfaces (opposite side surfaces located on opposite sides) of the sealing portion MR. Further, in FIG. 12, the level difference DS is a plane substantially parallel to the Z direction (thickness direction of sealing portion MR), but as another form, the step DS may be inclined at a predetermined angle with respect to the Z direction. The plane MRb1 and the plane MRb2 divided by the level difference DS are adjacent to each other in the Y-direction. In the present embodiment 2, the back surface DP1b of the die pad DP1 is covered with the sealing portion MR and is not exposed from the sealing portion MR, while the back surface DP2b of the die pad DP2 is exposed from the main surface MRb of the sealing portion MR.

That is, in the present embodiment 2, the die pad DP2 is sealed in the sealing portion MR except for the back surface DP2b, and is not exposed from the sealing portion MR, but the embodiment 1 is the same in that the back surface DP2 of the die pad DP2 is exposed from the main surface MRb of the sealing portion MR. However, unlike the embodiment 1 described above, in the present embodiment 2, the die pad DP1 is also covered with the sealing portion MR on the back surface DP2b, so that the die pad DP2 is not exposed from the sealing portion MR. However, in the present embodiment 2, among the surface MRb1, the surface MRb2, and the level difference DS constituting the main surface MRb of the sealing portion MR, the back surface DP2 of the die pad DP2 is exposed from the surface MRb2. In present embodiment 2, the die pad DP1 is enclosed in a plane MRb1 in a plan view, and a sealing portion MR exists between the plane MRb1 and the back surface DP2 of the die pad DP2.

Similarly to the embodiment 1, in the present embodiment 2, the height position of the die pad DP1 and the height position of the die pad DP2 are the same as each other. Therefore, the height position of the die pad DP1 on the chip mounting surface DP1a and the height position of the die pad DP2 on the chip mounting surface DP2a are the same as each other. In addition, the height position of the back surface DP1b of the die pad DP1 and the height position of the back surface DP2b of the die pad DP2 are the same as each other. The thickness of the die pad DP1 and the thickness of the die pad DP2 are the same as each other.

In addition, in the above embodiment 1, the outer lead portions of the respective lead LD1, LD2 are bent toward the main surface MRb of the sealing portion, but in the present embodiment 2, the outer lead portions of the respective lead LD1, LD2 are bent toward the main surface MRa of the sealing portion. Specifically, the outer lead portions of the respective lead LD1, LD2 are bent so that the lower surface near the end portion of the outer lead portion is located on substantially the same plane as the main surface MRa of the sealing portion MR.

Therefore, in the present embodiment 2, the sealing portion MR has a main surface MRb of upper surface, and the sealing portion MR has a main surface MRa of a lower surface. When the semiconductor device PKG2 is mounted on a mounting substrate or the like, the semiconductor device PKG2 is mounted on the mounting substrate so that the main surface MRa of the sealing part MR serves as the mounting surface and the main surface MRa of the sealing part MR faces the mounting substrate PB.

Other configurations of the semiconductor device PKG2 of the present embodiment 2 are substantially the same as those of the semiconductor device PKG1 of the present embodiment 2, and therefore, repeated explanation thereof will be omitted here.

The manufacturing step of the semiconductor device PKG2 of the present embodiment 2 is different from that of the present embodiment 1 in the following points.

That is, by performing the molding step, to form a sealing portion MR, the sealing portion MR is provided with a portion corresponding to the level difference DS in the mold for forming the sealing portion MR so that the sealing portion MR has a step DS at the stage where the sealing portion is formed. Alternatively, it is also possible to form a step DS on the sealing portion MR by grinding or polishing after forming the sealing portion MR having no step DS in the molding step. The former (contrivance of the mold) can simplify the manufacturing step.

In addition, in the present embodiment 2, the bending direction in bending the lead LD1, LD2 is opposite to the bending direction in the embodiment 1.

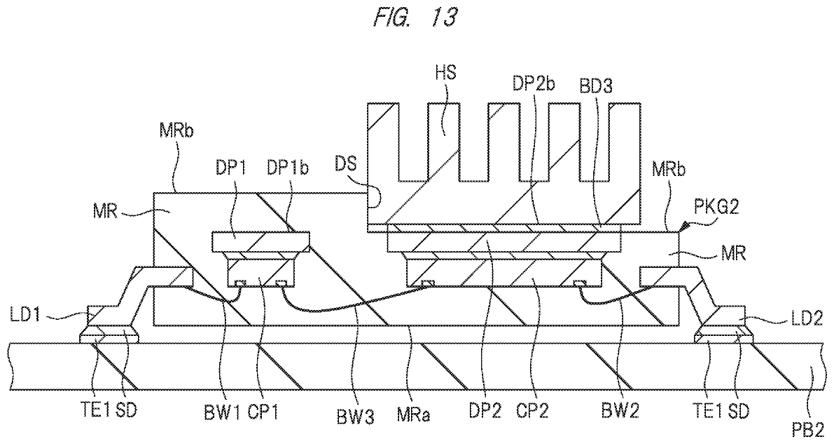

FIG. 13 is a cross-sectional view showing a state that the semiconductor device PKG2 of the present embodiment 2 is mounted on a mounting substrate (wire substrate) PB2. The cross section of the semiconductor device PKG2 shown in FIG. 13 corresponds to the cross section of FIG. 12 above.

As shown in FIG. 13, the semiconductor device PKG2 is mounted on the mounting substrate PB2 such that the main surface MRa of the sealing portion MR faces the mounting substrate PB2. Each of the lead LD1, LD2 of the semiconductor device PKG2 is electrically connected to and fixed to the terminal TEL of the mounting substrate PB2 via a conductive bonding material such as a solder SD.

In FIG. 13, a heat sink (heat dissipation member) HS is disposed and bonded to an exposed portion (back surface DP2b) of the die pad DP2 from the main surface MRb of the sealing portion MR via a bonding material BD3. The heat generated in the semiconductor chip CP2 is conducted to the heat sink HS via the bonding material BD2, the die pad DP2, and the bonding material BD3, and is dissipated to the outside air from the heat sink HS. As the bonding material BD, it is preferable to use a bonding material having a higher thermal conductivity. Further, as shown in FIG. 13, since the heat sink HS can be arranged adjacently to the level difference DS of the sealing portion MR, the positioning of the heat sink HS becomes easy when the heat sink HS is arranged on the semiconductor device PKG2. In some cases, the heat sink HS is not disposed, heat generated in the semiconductor-chip CP2 is conducted to the die pad DP2 through the bonding material BD2, and is dissipated to the outside air from the back surface DP2b of the die pad DP2.

In the semiconductor device PKG2 of present embodiment 2, the back surface DP2b of the die pad DP2 is exposed from the main surface MRb of the sealing portion MR, but the back surface DP1b of the die pad DP1 is not exposed. Since one of the die pad DP1, DP2 (die pad DP1) is not exposed from the sealing portion MR (back surface MRb of the semiconductor chip CP1), no discharge (corona discharge, creeping discharge) occurs between the die pad DP1 and the die pad DP2 even if a high potential difference occurs between the die pad DP1 on which the semiconductor chip CP2 is mounted and the die pad OOI on which the semiconductor chip is mounted. In addition, in the semiconductor device PKG2 of the present embodiment 2, the back surface of the semiconductor chip CP1 on which the semiconductor chip CP2 having a larger calorific value than that of the semiconductor chip is mounted is exposed from the main surface MRb of the sealing portion MR, so that the heat generated in the semiconductor chip CP2 is easily emitted to the outside of the semiconductor device PKG2 from the die pad DP2.

In the semiconductor device PKG2 of present embodiment 2, the height position of the die pad DP1 and the height position of the die pad DP2 are the same in the thickness direction (Z direction) of the sealing portion MR. Therefore, it is easy to perform the wire bonding step at the time of manufacturing the semiconductor device PKG2. That is, in the wire bonding step, the die pad DP1, DP2 is easily supported because the wire CP1, CP2 needs to be connected to the pad of the semiconductor chip mounted on the die pad BW1, BW2, BW3 while the die pad DP1 is supported, but the height positions of the die pad CP1, CP2 and the die pad DP2 are the same. Therefore, the semiconductor device PKG2 of the present embodiment 2 facilitates the process control of the wire bonding step at the time of manufacturing. In addition, the manufacturing yield of the semiconductor device PKG2 can be improved, and the manufacturing cost of the semiconductor device PKG2 can be suppressed.

According to the present embodiment 2, it is possible to accurately obtain a configuration in which the back surface MR of the die pad MRb is not exposed, although the back surface DP2b of the die pad DS is exposed from the main surface MRb of the sealing portion MR even if the height position of the die pad DP1 and the height position of the die pad DP2 are the same as each other by providing the level difference DP2 on the main surface DP1b of the sealing portion. That is, by using the level difference MR of the sealing portion DS, the structure pad DP1 is not exposed from the sealing portion DP2, but the back surface DP2b of the die pad DP1 is exposed from the main surface MRb of the sealing portion.

In the semiconductor device PKG2 of the present embodiment 2, the outer lead portions of the respective lead LD1, LD2 are bent toward the main surface MRa of the sealing portion MR. Reflecting this, as shown in FIG. 13, when the semiconductor device PKG2 is mounted on a mounting substrate PB2 or the like, the semiconductor device PKG2 is mounted on the mounting substrate PB2 such that the main surface MRa of the sealing portion MR serves as a mounting surface and the main surface MRa of the sealing portion MR faces the mounting substrate PB. Therefore, when the semiconductor device PKG2 is mounted on a mounting substrate PB2 or the like, the level difference DS in the main surface MRb of the sealing portion MR does not become an obstacle.

### Embodiment 3

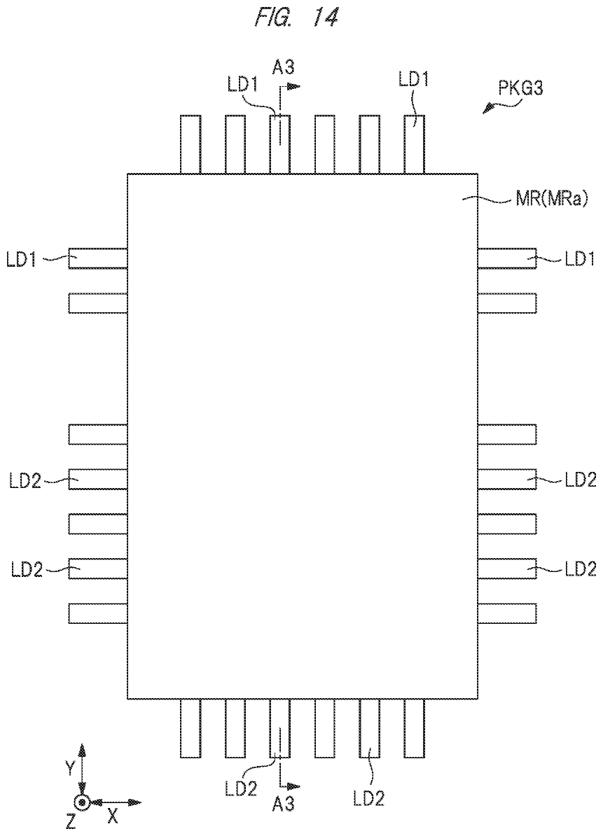

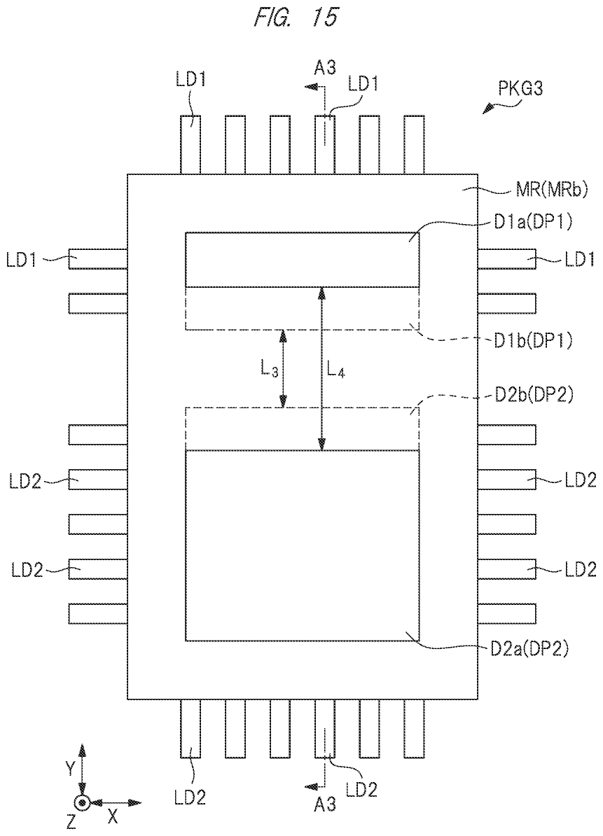

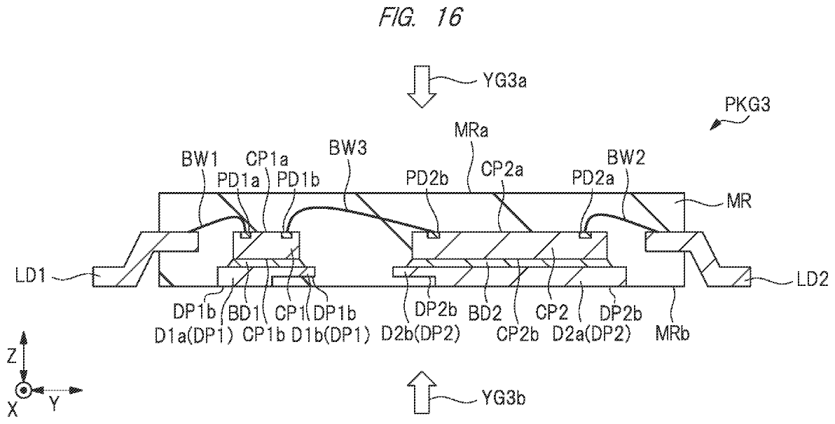

The construction of a semiconductor device PKG3 of the present embodiment 3 will be described referring to FIGS. 14 to 16. FIG. 14 and FIG. 15 are a plan view of the semiconductor device PKG3 according to the present embodiment 3, and FIG. 16 is a cross-sectional view of the semiconductor device PKG3 according to the present embodiment 3. FIG. 16 corresponds to a cross section at the position of A3-A3 in FIGS. 14 and 15.

Note that FIG. 14 corresponds to the plan view (upper surface diagram) of the semiconductor device PKG3 when the semiconductor device PKG3 is viewed from the arrow YG3a in FIG. 16. FIG. 15 corresponds to the plan view (bottom view) of the semiconductor device PKG3 when the semiconductor device PKG3 is viewed from the arrow YG3b in FIG. 16. Further, when looking at the semiconductor device PKG3 from the arrow YG3a in FIG. 16, a perspective plan view of the semiconductor device PKG3 seen through the sealing portion MR is substantially the same as in FIG. 3, and therefore, the illustration thereof is omitted here.

The semiconductor device PKG3 according to the embodiment 3 will be described below with a focus on the difference between the semiconductor device PKG1 of the embodiment 1 and the semiconductor device PKG3 of the embodiment 3.

In the semiconductor device PKG3 of the present embodiment 3, the groove TR is not formed on the main surface MRb of the sealing portion MR. Therefore, in present embodiment 3, the main surface MRb of the sealing portion MR is a flat surface (more specifically, a flat surface substantially parallel to the X direction and the Y direction). As in the embodiment 1, in present embodiment 3, the main surface MRa of the sealing portion MR is a flat surface (more specifically, a flat surface substantially parallel to the X direction and the Y direction).

In the semiconductor device PKG3 of the present embodiment 3, the die pad DP1 integrally includes the thick portion D1a and the thin portion Dlb thinner than the thick portion D1a. Further, the die pad DP2 integrally includes a thick portion D2a and a thin portion D2b thinner than the thick portion D2a. The thick portion D1a is a portion having a large thickness in the die pad DP1, and the thin portion D1b is a portion having a small thickness in the die pad DP1. The thick portion D2a is a portion having a large thickness in the die pad DP2, and the thin portion D2b is a portion having a small thickness in the die pad DP2.

The chip mounting surface DP1a of the die pad DP1 and the chip mounting surface DP2a of the die pad DP2 are flat surfaces (more specifically, flat surfaces substantially parallel to the X direction and the Y direction). The back surface DP1b of the die pad DP1 has a step at a boundary between the thick portion D1a and the thin portion D1b. The thick portion D1a has a substantially uniform thickness, the thin portion D1b has a substantially uniform thickness, and the thickness of the thin portion D1b is smaller than the thickness of the thick portion D1a. The back surface DP2b of the die pad DP2 has a step at a boundary between the thick portion D2a and the thin portion D2b. The thick portion D2a has a substantially uniform thickness, the thin portion D2b has a substantially uniform thickness, and the thickness of the thin portion D2b is smaller than the thickness of the thick portion D2a.

From the main surface MRb of the sealing portion MR, the thick portion DP1 of the die pad D2b and the thick portion D2a of the die pad DP2 are exposed, and the thin portion D1b of the die pad DP1 and the thin portion DP1 of the die pad MR are not exposed from the main surface MRb of the sealing portion.

That is, in the present embodiment 3, the die pad DP1 except the back surface DP1b in the thick portion D1a is sealed with the sealing portion MR and is not exposed from the sealing portion MR, but the back surface DP1b in the thick portion D1a of the die pad DP1 is exposed from the sealing portion MR at the main surface MRb of the sealing portion MR. Further, the die pad DP2 except the back surface DP2b in the thick portion D2a is sealed with the sealing portion MR and is not exposed from the sealing portion MR, but the back surface DP2b in the thick portion D2a of the die pad DP2 is exposed from the sealing portion MR at the main surface MRb of the sealing portion MR. Since the back surface DP1b in the thin portion D1b of the die pad DP1 and the back surface DP2b in the thin portion D2b of the die pad DP2 are covered with the sealing portion MR, they are not exposed from the sealing portion MR at the main surface MRb of the sealing portion MR.

Also, in the present embodiment 3, the height position of the die pad DP1 and the height position of the die pad DP2 are the same as each other. Therefore, the height position of the die pad DP1 on the chip mounting surface DP1a and the height position of the die pad DP2 on the chip mounting surface DP2a are the same as each other. In addition, the height position of the back surface DP1b in the thick portion D1a of the die pad DP1 and the height position of the back surface DP2b in the thick portion D2a of the die pad DP2 are the same as each other. The thickness of the thick portion D1a of the die pad DP1 and the thickness of the thick portion D2a of the die pad DP2 are the same as each other. When the thickness of the thick portion D1a of the die pad DP1 and the thickness of the thick portion D2a of the die pad DP2 are the same, the semiconductor device PKG3 can be easily manufactured using the lead frame. Further, in FIG. 16, the thickness of the thin portion D1b of the die pad DP1 and the thickness of the thin portion D2b of the die pad DP2 are the same as each other, but they may be different from each other.

The die pad DP1 and the die pad DP2 are spaced apart from each other in the Y direction, but the thin portion D1b of the die pad DP1 and the thin portion D2b of the die pad DP2 face each other in the Y direction. That is, in the die pad DP1, the thick portion D1a and the thin portion D1b are adjacent to each other in the Y-direction, the thin portion D1b is located on the side close to the die pad DP2, and the thick portion D1a is located on the side far from the die pad DP2. Further, in the die pad DP2, the thick portion D2a and the thin portion D2b are adjoined in the Y-direction, the thin portion D2b is located on the side close to the die pad DP1, and the thick portion D2a is located on the side far from the die pad DP1. That is, in plan view, between the thick portion D1a of the die pad DP1 and the thick portion D2a of the die pad DP2, the thin portion D1b of the die pad DP2 and the thin portion D2b of the die pad are disposed.

The semiconductor chip CP1 is mounted on the die pad DP1 via a bonding material BD1 so as to stride over the thick portion D1a and the thin portion D1b. Therefore, a thick portion D1a and a thin portion D1b of the die pad DP1 exist below the semiconductor chip CP1. That is, the semiconductor chip CP1 has a portion overlapping the thick portion D1a and a portion overlapping the thin portion D1b in plan view. The semiconductor chip CP2 is mounted on the die pad DP2 via a bonding material BD2 so as to stride over the thick portion D2a and the thin portion D2b. Therefore, a thick portion D2a and a thin portion D2b of the die pad DP2 exist below the semiconductor chip CP2. That is, the semiconductor chip CP2 has a portion overlapping the thick portion D2a and a portion overlapping the thin portion D2b in plan view.

Other configurations of the semiconductor device PKG3 of the present embodiment 3 are substantially the same as those of the semiconductor device PKG1 of the present embodiment 1, and therefore, repeated explanation thereof will be omitted here.

The manufacturing step of the semiconductor device PKG3 of the present embodiment 3 is different from that of the present embodiment 1 in the following points.

That is, a lead frame having a lead LD1, LD2 and a die pad DP1, DP2 is prepared, wherein the die pad DP1 has a thick portion D1a and a thin portion D1b, and the die pad DP2 has a thick portion D2a and a thin portion D2b. For example, a thin portion D1b, D2b that is relatively thinner than the thick portion D1a, D2a can be formed by, for example, half-etching a lead frame (or a metallic plate for forming a lead frame) from the back side. When the thickness of the thin portion D1b of the die pad DP1 and the thickness of the thin portion D1b of the die pad are the same as each other, the processing of the lead frame becomes easy.

In the present embodiment 3, in the sealing portion MR forming step, the groove portion TR may not be formed on the sealing portion MR. In this respect, the manufacturing step can be simplified.

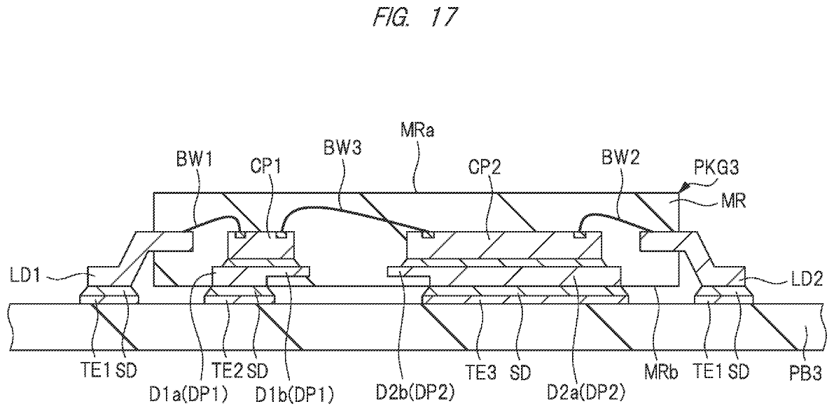

FIG. 17 is a cross-sectional view showing a state that the semiconductor device PKG3 according to the present embodiment 3 is mounted on a mounting substrate (wire substrate) PB3. The cross section of the semiconductor device PKG3 shown in FIG. 17 corresponds to the cross section of the above FIG. 16.

As shown in FIG. 16, the semiconductor device PKG3 is mounted on the mounting substrate PB3 such that the main surface MRb of the sealing portion MR faces the mounting substrate PB3. Each of the lead LD1, LD2 of the semiconductor device PKG3 is electrically connected to and fixed to the terminal TE1 of the mounting substrate PB3 via a conductive bonding material such as a solder SD.

In case of FIG. 16, the exposed portion (back surface of thick portion D1a) of the die pad DP1 from the main surface MRb of the sealing portion MR and the exposed portion (back surface of thick portion D2a) of the die pad DP2 are respectively connected to the terminal TE2, TE3 of the mounting substrate PB1 via a conductive bonding material such as solder SD. In this case, heat generated in the semiconductor chip CP1 is conducted through the bonding material BD1, the die pad DP1, and the solder SD to the mounting substrate PB1 to be dissipated, and heat generated in the semiconductor chip CP2 is conducted to the mounting substrate PB1 through the bonding material BD2, the die pad DP2, and the solder SD to be dissipated.

In the semiconductor device PKG3 of the embodiment 3, since the thick portion D1a (back surface) of the die pad DP1 and the thick portion D2a (back surface) of the die pad DP2 are exposed from the sealing portion MR at the mains surface MRb of the sealing portion MR, the heat generated in the semiconductor chip CP1, CP2 is easily emitted to the outside of the semiconductor device PKG1. As a consequence, it is possible to suppress an increase in the temperature of the semiconductor chip CP1, CP2 (particularly, semiconductor chip CP2) when the semiconductor device PKG1 is operated, and thus it is possible to improve the performance of the semiconductor device PKG3.

In addition, in the present embodiment 3, the die pad DP1 has a thick portion D1a and a thin portion D1b, and the die pad DP2 has a thick portion D2a and a thin portion D2b. The thin portion D1b of the die pad DP1 and the thin portion DP1b of the die pad DP2 face each other, and the thin portion D2b of the die pad MR is not exposed from the main surface MRb of the sealing portion MR and the thick portion D1a, D2a of the die pad DP1, DP2 is exposed, respectively, and from the main surface MR of the sealing portion. Accordingly, it is possible to suppress or prevent a discharge from occurring between exposed portions of the die pad DP1, DP2 on the main surface MRb of the sealing portion MR. The reason for this will be described below.

When the semiconductor device PKG3 of the present embodiment 3 is compared with the semiconductor device PKG101 of the examined example 1 shown in FIG. 6, it is assumed that the distance between the die pad DP1, DP2 and the distance between the die pad DP101, DP102 are the same. Here, the distance (creepage distance) between the exposed portions of the die pad DP1, DP2 in the main surface MRb of the sealing portion MR in present embodiment 3 is larger than the distance (creepage distance) between the exposed portions of the die pad DP101, DP102 in the main surface MR101b of the sealing portion MR101 in the examined example 1 shown in FIG. 6.

Here, the distance L₃ illustrated in FIG. 15 is a distance between the die pads DP1, DP2, and corresponds to a distance in the Y-direction between the thin portion D1b of the die pad DP1 and the thin portion D2b of the die pad DP2. Therefore, the distance L₃ is the same as the distance P₁ (see FIG. 2) (i.e., “L₃=P₁”). The distance La shown in FIG. 15 is a distance in the Y-direction between the thick portion DP1 of the interval pad D1a and the thick portion D1a of the die pad. Unlike present embodiment 3, when the thickness of the thin portion D1b, D2b is the same as the thickness of the thick portion D1a, D2a and the entire back surface of the die pad DP1, DP2 is exposed from the main surface MR of the sealing portion (corresponding to the examined example 1 in FIG. 6), the distance (creepage distance) between the exposed portions of the die pad DP1, DP2 in the main surface MRb of the sealing portion MR is the same as the distance L₃ shown in FIG. 15. On the other hand, in the present embodiment 3, the thick portion D1a, D2a of the die pad DP1, DP2 is exposed from the sealing portion MR at the main surface MRb of the sealing portion MR, but the thin portion D1b, D2b of the die pad DP1, DP2 is not exposed from the sealing portion MR at the main surface MRb of the sealing portion MR. Therefore, the distance (creepage distance) between the exposed portions of the die pads DP1, DP2 at the main surface MRb of the sealing portion MR is the same as the distance La shown in FIG. 15.

In the present embodiment 3, it is possible to increase the distance (creepage distance) between the exposed portions of the die pads DP1, DP2 at the main surface MRb of the sealing portion MR by arranging the thin portions D1b, D2b of the die pads DP1, DP2 next to each other and causing the main surface MRb of the sealing portion MR to expose the thick portion D1a, D2a of the die pad DP1, DP2 but not expose the thin portion D1b, D2b. As the distance (creepage distance) between the exposed portions of the die pad MR on the main surface MRb of the sealing portion MR is increased, a discharge is less likely to occur between the exposed portions of the die pad DP1, DP2 on the main surface MRb of the sealing portion. In the present embodiment 3, it is possible to suppress or prevent the occurrence of a discharge between exposed portions (back surface DP1, DP2) of the die pad DP1, DP2 on the main surface MRb of the sealing portion MR by causing the thin portions D1b, D2b of the die pad DP1b, DP2b to face each other and preventing the thin portion D1b, D2b of the die pad DP1, DP2 from being exposed on the main surface MRb of the sealing portion MR.

Further, in present embodiment 3, even if the distance (distance L₃) between the die pad DP1, DP2 is not increased, the creepage distance (distance L4) between the exposed portions of the die pad DP1, DP2 on the main surface MRb of the sealing portion MR can be increased. Therefore, the planar dimension (planar area) of the semiconductor device PKG3 can be suppressed. In addition, it is possible to prevent or prevent the wire BW3 from contacting each other when the sealing portion MR is formed.

Further, in present embodiment 3, the semiconductor chip CP1 is mounted on the thick portion D1a of the die pad DP1 and the thin portion D1b via the bonding material BD1, and the semiconductor chip CP2 is mounted on the thick portion D2a and the thin portion DP2 of the die pad via the bonding material BD2. Therefore, the semiconductor chip CP1 has a portion overlapping the thick portion D1a and a portion overlapping the thin portion D1b in a plan view, and the semiconductor chip CP2 has a portion overlapping the thick portion D2a and a portion overlapping the thin portion D2b in a plan view.

Unlike present embodiment, it is assumed that the semiconductor chip CP1 is mounted only on the thick portion D1a of the die pad DP1, the semiconductor chip CP1 does not have a portion that overlaps the thin portion D1b in a plan view, and the semiconductor chip CP2 does not have a portion that overlaps the thin portion D2b in a plan view, and the semiconductor chip D1a is mounted only on the thick portion D2a of the die pad DP2. In this case, since the thin portion D1b, DP2b of the die pad DP1, DP2 does not contribute to the mounting area of the semiconductor chip CP1, CP2, it can be eliminated. However, in present embodiment 3, the semiconductor chip CP1 is mounted on the thick portion D1a of the die pad DP1 and the thin portion D1b via the bonding material BD1, and the semiconductor chip CP2 is mounted on the thick portion D2a and the thin portion DP2 of the die pad via the bonding material BD2. Therefore, in the present embodiment 3, not only the thick portion D1a, D2a of the die pad DP1, DP2 but also the thin portion D1b, DP2b of the die pad DP1, DP2 contributes to the mounting area of the semiconductor chip CP1, CP2, so that the thin portion D1b, DP2b cannot be eliminated. That is, in the present embodiment 3, since it is intended to increase the creepage distance (distance L4) between the exposed portions of the die pad DP1, DP2 on the main surface MRb of the sealing portion MR, in the die pad DP1, DP2, the thin portion D1b, DP2b is provided at a position overlapping the semiconductor chip CP1, CP2 in plan view.

Further, it is assumed that, unlike present embodiment 3, the semiconductor chip CP1 is mounted only on the thin portion D1b of the die pad DP1, the semiconductor chip CP1 does not have a portion that overlaps the thick portion D1a in a plan view, and the semiconductor chip CP2 is mounted only on the thin portion D2b of the die pad DP2, and the semiconductor chip CP2 does not have a portion that overlaps the thick portion D2a in a plan view. In this case, since the thick portion D1a, D2a of the die pad DP1, DP2 does not exist directly under the semiconductor chip CP1, CP2, the heat generated in the semiconductor chip CP1, CP2 is less likely to be conducted to the thick portion D1a, D2a of the die pad DP1, DP2, and is less likely to be emitted to the outside of the semiconductor device PKG3 from the thick portion D1a, D2a of the die pad DP1, DP2.

On the other hand, present 3, in embodiment the semiconductor chip CP1 die pad DP1 is mounted on the thick portion D1a and the thin portion D1b, the semiconductor chip CP1 has a portion that overlaps the thick portion D1a in a plan view, and the semiconductor chip CP2 is mounted on the thick portion D2a and the thin portion D2b of the die pad DP2, and the semiconductor chip CP2 has a portion that overlaps the thick portion D2a in a plan view. Therefore, since the thick portion D1a, D2a of the die pad DP1, DP2 exists directly under the semiconductor chip CP1, CP2, the heat generated in the semiconductor chip CP1, CP2 is easily conducted to the thick portion D1a, D2a of the die pad DP1, DP2, and is easily discharged to the outside of the semiconductor device PKG3 from the thick portion D1a, D2a of the die pad DP1, DP2.

Therefore, in present embodiment, the boundary between the thick portion D1a and the thin portion D1b in the die pad DP1 is disposed at a position overlapping with the semiconductor chip CP1 in plan view, and the boundary between the thick portion D2a and the thin portion D2b in the die pad DP2 is disposed at a position overlapping with the semiconductor chip CP2 in plan view.

Also in present embodiment 3, the height position of the die pad DP1 and the height position of the die pad DP2 are the same in the thickness direction (Z direction) of the sealing portion MR. Therefore, it is easy to perform the wire bonding step at the time of manufacturing the semiconductor device PKG3. Therefore, it is easy to control the process of the wire bonding step at the time of manufacturing. In addition, the manufacturing yield of the semiconductor device PKG3 can be improved, and the manufacturing cost of the semiconductor device PKG3 can be suppressed.

### Embodiment 4

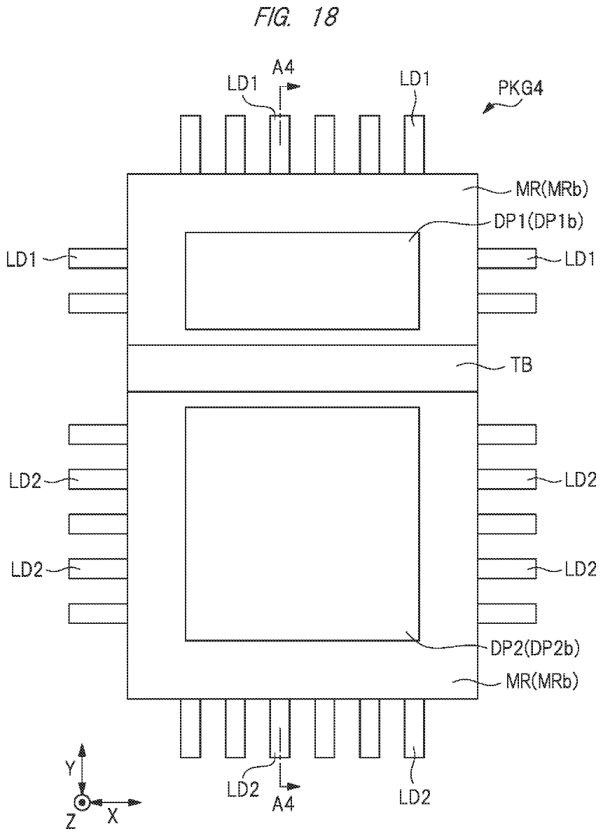

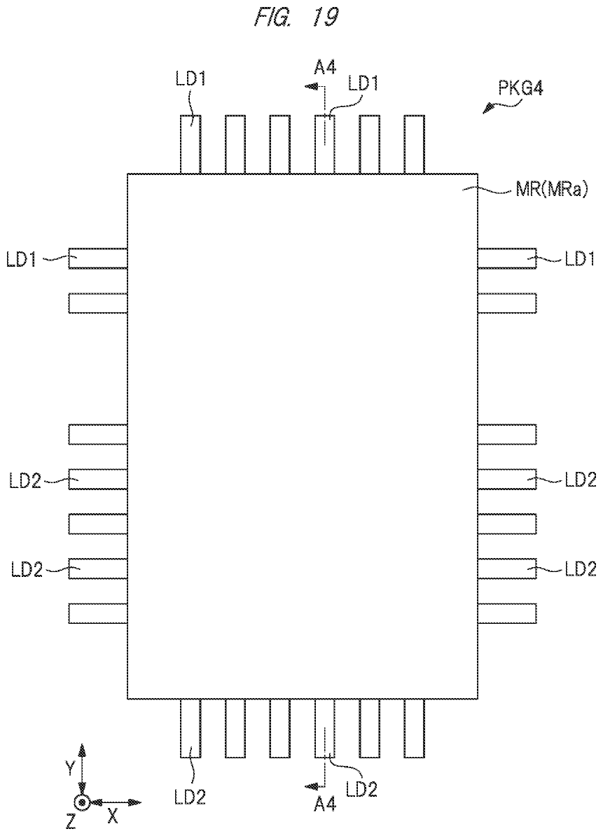

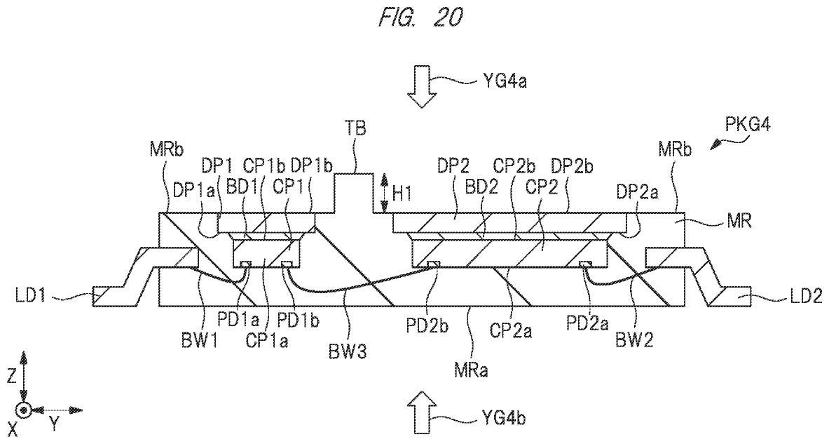

The construction of a semiconductor device PKG4 of the present embodiment 4 will be described by referring to FIG. 18 to FIG. 20. FIG. 18 and FIG. 19 are a plan view of the semiconductor device PKG4 according to the present embodiment 4, and FIG. 20 is a cross-sectional view of the semiconductor device PKG4 according to the present embodiment 4. FIG. 20 corresponds to a cross section at the position of A4-A4 in FIGS. 18 and 19.

Note that FIG. 18 corresponds to the plan view (upper surface diagram) of the semiconductor device PKG4 when the semiconductor device PKG4 is viewed from the arrow YG4a in FIG. 20. FIG. 19 corresponds to the plan view (bottom view) of the semiconductor device PKG4 when the semiconductor device PKG4 is viewed from the arrow YG4b in FIG. 20. Further, when looking at the semiconductor device PKG4 from the arrow YG4b in FIG. 20, a perspective plan view of the semiconductor device PKG4 seen through the sealing portion MR is substantially the same as in FIG. 3 above, and therefore, the illustration thereof is omitted here.

The semiconductor device PKG4 according to the embodiment 4 will be described below with a focus on the difference between the semiconductor device PKG1 of the embodiment 1 and the semiconductor device PKG4 of the embodiment 4.

In the semiconductor device PKG4 of the present embodiment 4, the groove TR is not formed on the main surface MRb of the sealing portion MR, and a protruding portion TB is formed instead of the groove TR. In the main surface MRb of the sealing portion MR, the formation position of the protruding portion TB is basically the same as the formation position of the trench TR. That is, in the main surface MR of the sealing portion MRb, between the exposed portion of the die pad DP1 (back surface DP1b) and the exposed portion of the die pad DP2 (back surface DP2b), the protruding portion TB of the sealing portion is formed. Specifically, in the main surface MRb of the sealing portion MR, the protruding portion TB is formed (extends) along the X-direction so as to cross the region between the exposed portion (back surface DP1b) of the die pad DP1 and the exposed portion (back surface DP2b) of the die pad DP2. The main surface MRb of the sealing portion MR is a substantially flat surface except for the protruding portion TB, but protrudes locally in the protruding portion TB. The protruding portion TB is constituted by a top surface (upper surface) and both side walls (both side surfaces), and the top surface and both side walls are substantially parallel to the X-direction.

In addition, in the above embodiment 1, the outer lead portions of the respective lead LD1, LD2 are bent toward the main surface MRb of the sealing portion, but in the present embodiment 4, the outer lead portions of the respective lead LD1, LD2 are bent toward the main surface MRa of the sealing portion. Specifically, the outer lead portions of the respective lead LD1, LD2 are bent so that the lower surface near the end portion of the outer lead portion is located on substantially the same plane as the main surface MRa of the sealing portion MR.

Therefore, in the present embodiment 4, the sealing portion MR has a main surface MRb of upper surface, and the sealing portion MR has a main surface MRa of a lower surface. When the semiconductor device PKG4 is mounted on a mounting substrate or the like, the semiconductor device PKG4 is mounted on the mounting substrate so that the main surface MRa of the sealing part MR serves as the mounting surface and the main surface MRa of the sealing part MR faces the mounting substrate PB.

Other configurations of the semiconductor device PKG4 of the present embodiment 4 are substantially the same as those of the semiconductor device PKG1 of present embodiment 1, and therefore, repeated explanation thereof will be omitted here.

The manufacturing step of the semiconductor device PKG4 of the present embodiment 4 is different from that of the present embodiment 1 in the following points.

That is, by performing the molding step, to form a sealing portion MR, a portion corresponding to the protrusion TB is provided in the mold for forming the sealing portion MR so that the sealing portion MR has a protrusion TB at the stage where the sealing portion is formed. Alternatively, it is also possible to form the protrusion TB on the sealing portion MR by forming the sealing portion MR having no protrusion TB in the molding step and then grinding or polishing the portion other than the portion serving as the protrusion TB in the main surface MRb of the sealing portion MR until the back surface DP1b, DP2b of the die pad DP1, DP2 is exposed. The former (contrivance of the mold) can simplify the manufacturing step.

In addition, in the present embodiment 4, the bending direction in bending the lead LD1, LD2 is opposite to the bending direction in the embodiment 1.

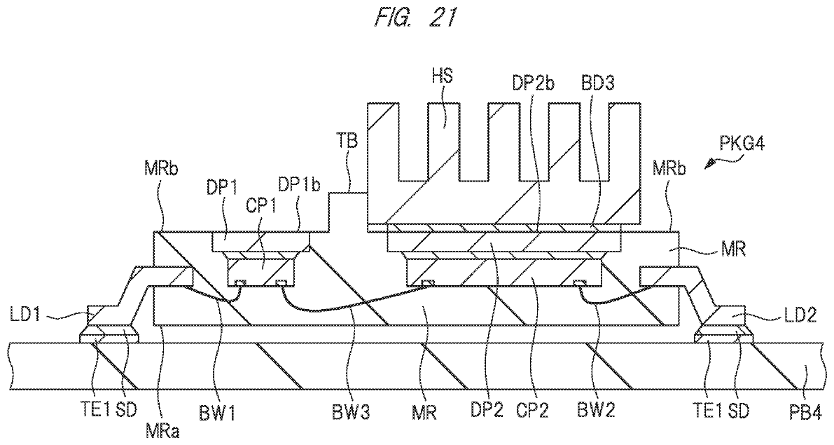

FIG. 21 is a cross-sectional view showing a state that the semiconductor device PKG4 of the present embodiment 4 is mounted on a mounting substrate (wire substrate) PB4. The cross section of the semiconductor device PKG4 shown in FIG. 21 corresponds to the cross section of FIG. 20.

As shown in FIG. 20, the semiconductor device PKG4 is mounted on the mounting substrate PB4 such that the main surface MRa of the sealing portion MR faces the mounting substrate PB4. Each of the lead LD1, LD2 of the semiconductor device PKG4 is electrically connected to and fixed to the terminal TEL of the mounting substrate PB4 via a conductive bonding material such as a solder SD.

In FIG. 21, a heatsink HS is disposed and bonded to an exposed portion (back surface DP2b) of the die pad DP2 from the main surface MRb of the sealing portion MR via a bonding material BD3. The heat generated in the semiconductor chip CP2 is conducted to the heat sink HS via the bonding material BD2, the die pad DP2, and the bonding material BD3, and is dissipated to the outside air from the heat sink HS. As the bonding material BD, it is preferable to use a bonding material having a higher thermal conductivity. Further, as shown in FIG. 21, since the heat sink HS can be arranged so as to adjoin the protruding portion TB of the sealing portion MR, the positioning of the heat sink HS becomes easy when the heat sink HS is arranged on the semiconductor device PKG4. In some cases, the heat sink HS is not disposed, heat generated in the semiconductor chip CP2 is conducted to the die pad DP2 through the bonding material BD2, and is dissipated to the outside air from the back surface DP2b of the die pad DP2.

Also in the present embodiment 4, since the sealing portion MR is exposed from the main surface MRb of the sealing portion DP1, DP2 to the back surface DP1b, DP2b of the die pad DP1, DP2, heat generated in CP1, CP2 of the semiconductor chip is easily discharged from the die pad DP1, DP2 to the outside of the semiconductor device PKG1.

Further, in the present embodiment, in the main surface MRb of the sealing portion MR, it is possible to suppress or prevent the occurrence of a discharge between the back surface DP1 of the die pad DP1 exposed from the main surface MRb of the sealing portion MR and the back surface DP2 of the die pad DP1b by forming the protruding portion TB of the sealing portion MR between the back surface DP2 of the die pad DP1b and the back surface DP2b of the die pad DP2b. The reason for this will be described below.

That is, in the present embodiment 4, in the main surface MR of the sealing portion MRb, the exposed portion of the die pad MRb (back surface DP1, DP2) in the main surface DP1, DP2 of the sealing portion DP1b, DP2b (corresponding to the examined example 1 in FIG. 6) by forming the convex portion TB of the sealing portion MR between the exposed portions of the die pad DP1b, DP2b (back surface DP1b, DP2b), as compared with the case where the convex portion TB is not formed (it corresponds to) it is possible to increase the creepage distance between. Consequently, a discharge is less likely to occur between exposed portions of the die pad DP1, DP2 on the main surface MRb of the sealing portion MR.

That is, when the convex portion TB is formed, when the discharge occurs between the exposed portion (back surface DP1b, DP2b) of the die pad DP1, DP2 in the main surface MRb of the sealing portion MR, since the discharge path will include both side walls and the top surface of the convex portion TB, as compared with the case where the convex portion TB is not formed, the discharge path becomes longer, result, the exposed portion of the die pad DP1, DP2 (back surface DP1b, DP2b) discharge is less likely to occur between. Therefore, as in the present embodiment, it is possible to suppress or prevent a discharge between exposed portions (back surface MR) of the die pad DP1, DP2 in the main surface MRb of the sealing portion DP1b, DP2b, by forming the exposed portions (back surface DP1b, DP2b) of the die pad DP1, DP2 between the exposed portions (back surface TB) of the sealing portion MR, the main surface MRb of the sealing portion MR.

Further, in the present embodiment 4, since the convex portion TB is provided on the main surface MRb of the sealing portion MR, it is possible to increase the creepage distance between the exposed portions (back surface DP1b, DP2b) of the die pad DP1, DP2 on the main surface MRb of the sealing portion MR without increasing the distance between the die pad DP1, DP2. Therefore, the planar dimension (planar area) of the semiconductor device PKG4 can be suppressed. In addition, it is possible to prevent or prevent the wire BW3 from contacting each other when the sealing portion MR is formed.

Further, in the main surface MRb of the sealing portion MR, the convex portion TB is formed so as to cross a region between the back surface DP1b of the die pad DP1 and the back surface DP2b of the die pad DP2 (refer to FIG. 18). Specifically, in the main surface MRb of the sealing portion MR, the back surface DP1b of the die pad DP1 and the back surface DP2b of the die pad DP2 are separated in the Y direction, and the convex portion TB extends in the X direction so as to cross a region between the back surface DP1b of the die pad DP1 and the back surface DP2b of the die pad MRb. Thus, in the main surface MRb of the sealing portion MR, a straight line connecting an arbitrary position of the exposed portion of the die pad DP1 (here, the back surface DP1b) and an arbitrary position of the exposed portion of the die pad DP2 (here, the back surface DP2b) is crossed by the convex portion TB. Therefore, since the dischargeable path between the exposed portions (back surface DP1b, DP2b) of the die pad DP1, DP2 in the main surface MRb of the sealing portion MR, the convex portion TB crosses, it is possible to accurately suppress or prevent the discharge between the exposed portions (back surface DP1b, DP2b) of the die pad DP1, DP2 in the main surface MRb of the sealing portion MR.

Further, in the main surface MRb of the sealing portion MR, since it is possible to suppress or prevent a discharge between exposed portions (back surface DP1b, DP2b) of the die pad DP1, DP2 on the main surface DP1 of the sealing portion MR as long as the convex portion TB crosses the region between the back surface DP1b of the die pad MR and the back surface DP2b of the die pad DP2, there may be cases where the convex portion TB has not reached the side surface of the sealing portion. However, it is more preferable that the convex portion TB reaches both side surfaces (both side surfaces located on opposite sides) of the sealing portion MR, so that the convex portion TB on the sealing portion MR can be easily formed, and the discharge-suppressing effect can also be enhanced.

Further, as the height H1 of the convex portion TB is increased, the creepage distance between the exposed portions (back surface DP1b, DP2b) of the die pad DP1, DP2 in the main surface MRb of the sealing portion MR is increased, so that a discharge is less likely to occur between the exposed portions (back surface DP1b, DP2b) of the die pad DP1, DP2. Therefore, it is preferable that the height TB of the sealing portion MR on the convex portion H1 is increased to some extent (increased), and in this viewpoint, it is preferable that the height H1 of the convex portion TB is larger than the respective thicknesses of the die pad DP1, DP2.

Also in the present embodiment 4, the height position of the die pad DP1 and the height position of the die pad DP2 are the same in the thickness direction (Z direction) of the sealing portion MR. Therefore, it is easy to perform the wire bonding step at the time of manufacturing the semiconductor device PKG4.

### Embodiment 5

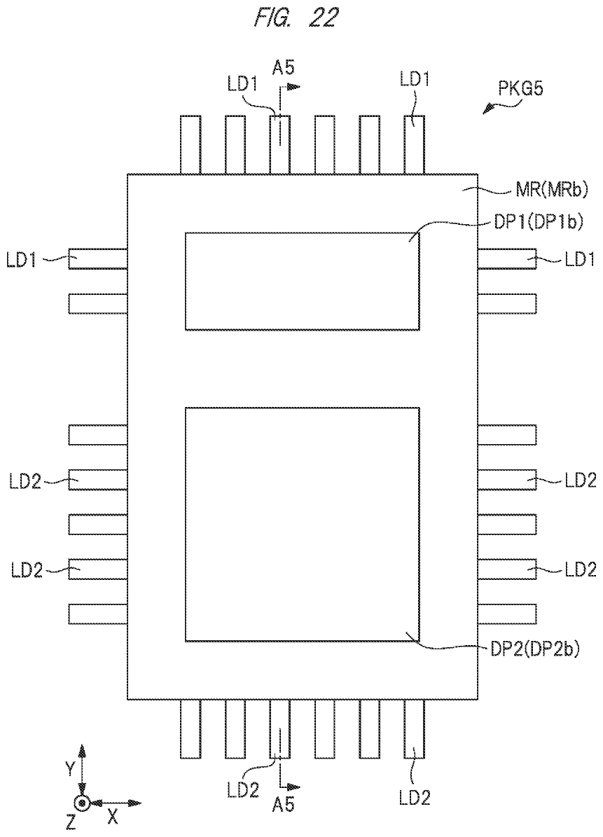

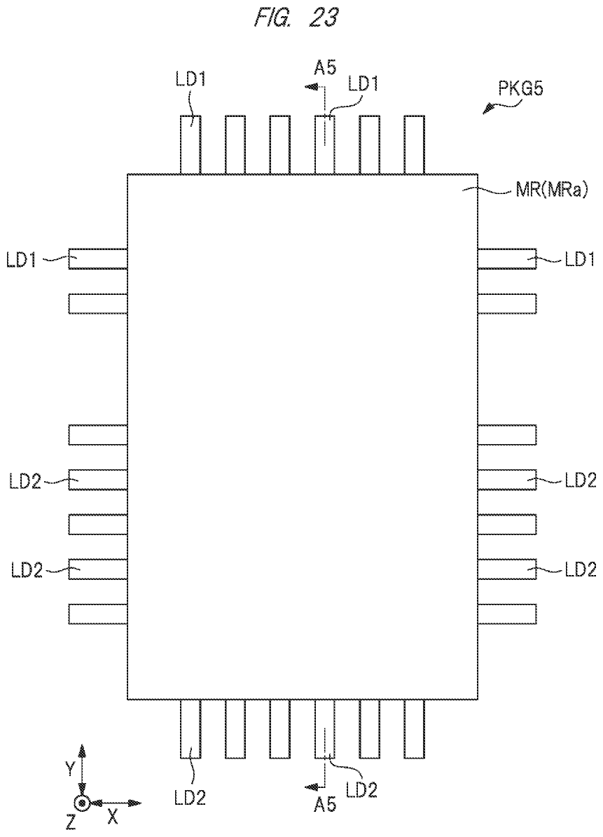

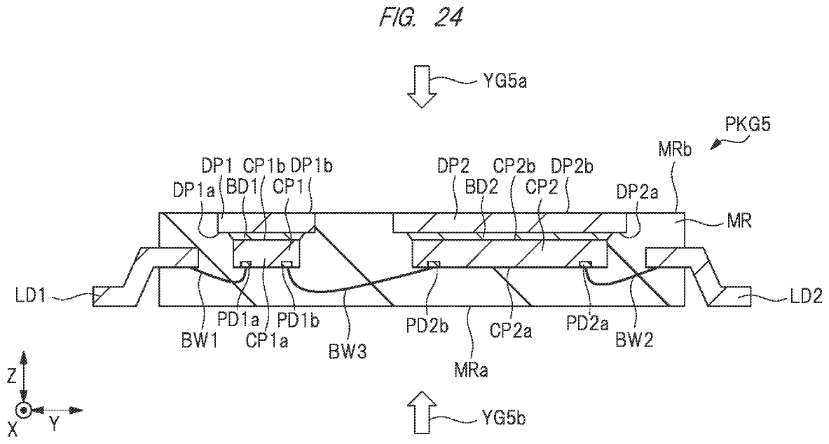

The construction of a semiconductor device PKG5 of the present embodiment 5 will be described by referring to FIG. 22 to FIG. 25. FIG. 22 and FIG. 23 are a plan view of the semiconductor device PKG5 according to the present embodiment 5, and FIG. 24 is a cross-sectional view of the semiconductor device PKG5 according to the present embodiment 5. FIG. 24 corresponds to a cross section at the position of A5-A5 in FIGS. 22 and 23. Note that FIG. 22 corresponds to the plan view (upper surface diagram) of the semiconductor device PKG5 when the semiconductor device PKG5 is viewed from the arrow YG5a in FIG. 24. FIG. 23 corresponds to the plan view (bottom view) of the semiconductor device PKG5 when the semiconductor device PKG5 is viewed from the arrow YG5b in FIG. 24. Further, when looking at the semiconductor device PKG5 from the arrow YG5b in FIG. 24, a perspective plan view of the semiconductor device PKG5 seen through the sealing portion MR is substantially the same as in FIG. 3, and therefore, the illustration thereof is omitted here.

The semiconductor device PKG5 according to the embodiment 5 will be described below with a focus on the difference between the semiconductor device PKG1 of the embodiment 1 and the semiconductor device PKG5 of the embodiment 5.

In the semiconductor device PKG5 of the present embodiment 5, the groove TR is not formed on the main surface MRb of the sealing portion MR, and the convex portion TB is not formed. Therefore, in present embodiment 5, the main surface MRb of the sealing portion MR is a flat surface (more specifically, a flat surface substantially parallel to the X direction and the Y direction). Similarly to the embodiment 1, in present embodiment 2, the main surface MRa of the sealing portion MR is a flat surface (more specifically, a flat surface substantially parallel to the X direction and the Y direction).

In addition, in the above embodiment 1, the outer lead portions of the respective lead LD1, LD2 are bent toward the main surface MRb of the sealing portion, but in the present embodiment 5, the outer lead portions of the respective lead LD1, LD2 are bent toward the main surface MRa of the sealing portion. Specifically, the outer lead portions of the respective lead LD1, LD2 are bent so that the lower surface near the end portion of the outer lead portion is located on substantially the same plane as the main surface MRa of the sealing portion MR.

Therefore, in the present embodiment 5, the sealing portion MR has a main surface MRb of upper surface, and the sealing portion MR has a main surface MRa of a lower surface. When the semiconductor device PKG5 is mounted on a mounting substrate or the like, the semiconductor device PKG5 is mounted on the mounting substrate so that the main surface MRa of the sealing part MR serves as the mounting surface and the main surface MRa of the sealing part MR faces the mounting substrate PB.

Other configurations of the semiconductor device PKG5 of the present embodiment 5 are substantially the same as those of the semiconductor device PKG1 of the present embodiment 1, and therefore, repeated explanation thereof will be omitted here.

The manufacturing step of the semiconductor device PKG5 of the present embodiment 5 is different from that of the present embodiment 1 in the following points.

That is, in the present embodiment 5, in the sealing portion MR forming step, the groove portion TR may not be formed on the sealing portion MR. In this respect, the manufacturing step can be simplified. However, in the present embodiment 5, after the semiconductor device PKG5 is mounted on the mounting substrate PB5, a resin portion PT forming step to be described later is required.

In addition, in the present embodiment 5, the bending direction in bending the lead LD1, LD2 is opposite to the bending direction in the embodiment 1.

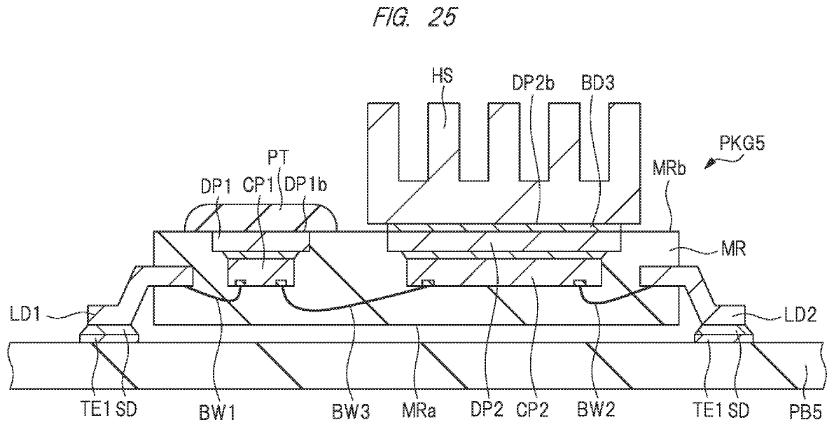

FIG. 25 is a cross-sectional view showing a state that the semiconductor device PKG5 of the present embodiment 5 is mounted on a mounting substrate (wire substrate) PB5. The cross section of the semiconductor device PKG5 shown in FIG. 25 corresponds to the cross section of FIG. 24.

As shown in FIG. 25, the semiconductor device PKG5 is mounted on the mounting substrate PB5 such that the main surface MRa of the sealing portion MR faces the mounting substrate PB5. Each of the lead LD1, LD2 of the semiconductor device PKG4 is electrically connected to and fixed to the terminal TEL of the mounting substrate PB5 via a conductive bonding material such as a solder SD.

Then, the heat-sink HS is disposed and bonded to the exposed portion (back surface DP2b) of the die pad DP2 from the main surface MRb of the sealing portion MR via the bonding material BD3. As a result, the heat generated in the semiconductor chip CP2 is conducted to the heat sink HS via the bonding material BD2, the die pad DP2, and the bonding material BD3, and can be radiated from the heat sink HS into the outside air. As the bonding material BD, it is preferable to use a bonding material having a higher thermal conductivity. In some cases, the heat sink HS is not disposed, heat generated in the semiconductor chip CP2 is conducted to the die pad DP2 through the bonding material BD2, and is dissipated to the outside air from the back surface DP2b of the die pad DP2.

In the present embodiment 5, after the semiconductor device PKG5 is mounted on the mounting substrate PB5, a resin portion (potting resin, sealing resin) PT is formed so as to cover the exposed portion (back surface DP1b) of the die pad DP1 from the main surface MRb of the sealing portion MR. When the heat sink HS is disposed on the back surface DP2b of the die pad DP2, it is preferable to form the resin portion PT after the heat sink HS is disposed.

The resin portion PT is made of, for example, a resin material such as a thermosetting resin material, and may include fillers and the like. For example, the resin portion PT can be formed using an epoxy-resin or the like containing fillers. The resin-part PT can be formed by a potting method or the like. For example, the resin portion PT can be formed by applying or dropping a resin material for resin portion PT so as to cover the back surface DP1b of the die pad DP1 exposed from the main surface MRb of the sealing portion MR, and then curing the resin material.

In the embodiment 5 of the semiconductor device PKG5, from the main surface MR of the sealing portion MRb, the back surface DP1, DP2 of the die pad DP1b, DP2b is exposed, but the resin portion PT is formed so as to cover the back surface DP1b of the die pad DP1 exposed from the main surface MR of the sealing portion after the semiconductor device PKG5 is mounted on the mounting substrate PB5. Therefore, in the step of operating the semiconductor device PKG5, the back surface DP1b of the die pad DP1 exposed from the main surface MRb of the sealing portion MR is covered with the resin portion PT and is not exposed. Therefore, even if a high-potential difference occurs between the die pad DP1 on which the semiconductor chip CP1 is mounted and the die pad CP2 on which the semiconductor chip DP2 is mounted, a discharge (corona discharge, creepage discharge) does not occur between the die pad DP1 and the die pad DP2.

Further, the sealing portion PT covers the back surface DP1b of the die pad DP1 exposed from the main surface MRb of the sealing portion MR, but does not cover the back surface DP2b of the die pad DP2 exposed from the main surface MRb of the sealing portion MR. Heat generated by the semiconductor chip CP2 can be emitted from the die pad DP2 to the outside of the semiconductor device PKG5 because the back surface DP2b of the die pad DP2 on which the semiconductor chip CP2 having a larger heat generation value than that of the semiconductor chip CP1 is mounted is not covered with the sealing portion PT.

Also in the present embodiment 5, the height position of the die pad DP1 and the height position of the die pad DP2 are the same in the thickness direction (Z direction) of the sealing portion MR. Therefore, it is easy to perform the wire bonding step at the time of manufacturing the semiconductor device PKG5.

When the semiconductor devices PKG˜PKG5 of the embodiments 1˜5 are compared to one another, the semiconductor devices PKG1, PKG3, PKG5 of the embodiments 1, 3, 5 have a better transportability than the semiconductor devices PKG2, PKG4 of the embodiments 2, 4. The reason for this is that the semiconductor device PKG2 according to the embodiment 2 has a step MR on the main surface of the sealing portion DS, and the semiconductor device PKG4 according to the embodiment 4 has a convex portion TB on the main surface of the sealing portion MR, thus there is a possibility that the transportability of the semiconductor device is to be lowered by the step DS and the convex portion, while there is no fear that the transportability of the semiconductor devices PKG1, PKG3, PKG5 according to the embodiments 1, 3, 5 is to be lowered.

The invention made by the present inventor has been described above in detail based on the embodiment, but the present invention is not limited to the embodiment described above, and it is needless to say that various modifications can be made without departing from the gist thereof.

What is claimed is:

1. A semiconductor device comprising:
a first chip mounting portion;
a second chip mounting portion;
a first semiconductor chip mounted on the first chip mounting portion, the first semiconductor chip having a plurality of first pad electrodes and a plurality of second pad electrodes;
a second semiconductor chip mounted on the second chip mounting portion, the second semiconductor chip having a plurality of third pad electrodes and a plurality of fourth pad electrodes;
a plurality of first lead portions;
a plurality of second lead portions;
a plurality of first wires electrically connecting the plurality of first pad electrodes of the first semiconductor chip with the plurality of first lead portions, respectively;
a plurality of second wires electrically connecting the plurality of third pad electrodes of the second semiconductor chip with the plurality of second lead portions, respectively;
a plurality of third wires electrically connecting the plurality of second pad electrodes of the first semiconductor chip with the plurality of fourth pad electrodes of the second semiconductor chip, respectively; and
a sealing portion sealing the first chip mounting portion, the second chip mounting portion, the first semiconductor chip, the second semiconductor chip, the plurality of first lead portions, the plurality of second lead portions, the plurality of first wires, the plurality of second wires and the plurality of third wires,
wherein the sealing portion has:
a first main surface; and
a second main surface opposite the first main surface,
wherein a groove portion is formed in the first main surface of the sealing portion,
wherein the first chip mounting portion has:
a first mounting surface on which the first semiconductor chip is mounted; and
a first back surface opposite the first mounting surface,
wherein the second chip mounting portion has:
a second mounting surface on which the second semiconductor chip is mounted; and
a second back surface opposite the second mounting surface,
wherein the first semiconductor chip is mounted on the first mounting surface of the first chip mounting portion via a first bonding material,
wherein the second semiconductor chip is mounted on the second mounting surface of the second chip mounting portion via a second bonding material,
wherein, at the first main surface of the sealing portion, each of the first back surface of the first chip mounting portion and the second back surface of the second chip mounting portion is exposed from the sealing portion, and
wherein, at the first main surface of the sealing portion, the groove portion is formed between the first back surface of the first chip mounting portion and the second back surface of the second chip mounting portion so as to cross a region between the first back surface of the first chip mounting portion and the second back surface of the second chip mounting portion.

2. The semiconductor device according to claim 1, wherein a second electric power is to be supplied to the second semiconductor chip, the second electric power being larger than a first electric power which is to be supplied to the first semiconductor chip.

3. The semiconductor device according to claim 1,
wherein the plurality of first lead portions has a first lead,
wherein the plurality of second lead portions has a second lead,
wherein the first lead and the second lead are arranged next to each other, and
wherein a distance between the first lead and the second lead along an outer surface of the sealing portion is larger than a distance between the first chip mounting portion and the second chip mounting portion.

4. The semiconductor device according to claim 1, wherein, in cross-sectional view, the first chip mounting portion is located at a same height as the second chip mounting portion.

5. The semiconductor device according to claim 1, wherein, in cross-sectional view, a bottom surface of the groove portion is located higher than each of the first mounting surface of the first chip mounting portion and the second mounting surface of the second chip mounting portion.

6. The semiconductor device according to claim 5,
wherein the first semiconductor chip has:
a first surface; and
a second surface opposite the first surface,
wherein the second semiconductor chip has:
a third surface; and
a fourth surface opposite the third surface,
wherein the first semiconductor chip is mounted on the first mounting surface of the first chip mounting portion via the first bonding material such that the second surface of the first semiconductor chip faces the first mounting surface of the first chip mounting portion,
wherein the second semiconductor chip is mounted on the second mounting surface of the second chip mounting portion via the second bonding material such that the fourth surface of the second semiconductor chip faces the second mounting surface of the second chip mounting portion, and
wherein, in a thickness direction of the sealing portion, the bottom surface of the groove portion is located lower than each of the first surface of the first semiconductor chip and the third surface of the second semiconductor chip.

7. The semiconductor device according to claim 1, wherein a width of the groove portion is 1.5 mm or more.

8. A semiconductor device comprising:
a first chip mounting portion;
a second chip mounting portion;
a first semiconductor chip mounted on the first chip mounting portion, the first semiconductor chip having a plurality of first pad electrodes and a plurality of second pad electrodes;
a second semiconductor chip mounted on the second chip mounting portion, the second semiconductor chip having a plurality of third pad electrodes and a plurality of fourth pad electrodes;
a plurality of first lead portions;
a plurality of second lead portions;
a plurality of first wires electrically connecting the plurality of first pad electrodes of the first semiconductor chip with the plurality of first lead portions, respectively;
a plurality of second wires electrically connecting the plurality of third pad electrodes of the second semiconductor chip with the plurality of second lead portions, respectively;
a plurality of third wires electrically connecting the plurality of second pad electrodes of the first semiconductor chip with the plurality of fourth pad electrodes of the second semiconductor chip, respectively; and
a sealing portion sealing the first chip mounting portion, the second chip mounting portion, the first semiconductor chip, the second semiconductor chip, the plurality of first lead portions, the plurality of second lead portions, the plurality of first wires, the plurality of second wires and the plurality of third wires,
wherein the sealing portion has:
a first main surface; and
a second main surface opposite the first main surface, wherein the first chip mounting portion has:
a first mounting surface on which the first semiconductor chip is mounted; and
a first back surface opposite the first mounting surface,
wherein the second chip mounting portion has:
a second mounting surface on which the second semiconductor chip is mounted; and
a second back surface opposite the second mounting surface,
wherein the first semiconductor chip is mounted on the first mounting surface of the first chip mounting portion via a first bonding material,
wherein the second semiconductor chip is mounted on the second mounting surface of the second chip mounting portion via a second bonding material,
wherein, in a thickness direction of the sealing portion, the first chip mounting portion is located at a same height as the second chip mounting portion, and
wherein, at the first main surface of the sealing portion, the second back surface of the second chip mounting portion is exposed from the sealing portion, but the first back surface of the first chip mounting portion is not exposed from the sealing portion.

9. The semiconductor device according to claim 8, wherein a second electric power is to be supplied to the second semiconductor chip, the second electric power being larger than a first electric power which is to be supplied to the first semiconductor chip.

10. The semiconductor device according to claim 8,
wherein the plurality of first lead portions has a first lead,
wherein the plurality of second lead portions has a second lead,
wherein the first lead and the second lead are arranged next to each other, and
wherein a distance between the first lead and the second lead along an outer surface of the sealing portion is larger than a distance between the first chip mounting portion and the second chip mounting portion.

11. The semiconductor device according to claim 8,
wherein a step is formed in the sealing portion at the first main surface of the sealing portion, and
wherein, at the first main surface of the sealing portion, the step is formed between the first chip mounting portion and the second chip mounting portion so as to cross a region between the first chip mounting portion and the second chip mounting portion.

12. The semiconductor device according to claim 11, wherein an outer lead portion of each of the plurality of first lead portions and the plurality of second lead portions is bended toward the second main surface of the sealing portion.

13. A semiconductor device comprising:
a first chip mounting portion;
a second chip mounting portion;
a first semiconductor chip mounted on the first chip mounting portion, the first semiconductor chip having a plurality of first pad electrodes and a plurality of second pad electrodes;
a second semiconductor chip mounted on the second chip mounting portion, the second semiconductor chip having a plurality of third pad electrodes and a plurality of fourth pad electrodes;
a plurality of first lead portions;
a plurality of second lead portions;
a plurality of first wires electrically connecting the plurality of first pad electrodes of the first semiconductor chip with the plurality of first lead portions, respectively;
a plurality of second wires electrically connecting the plurality of third pad electrodes of the second semiconductor chip with the plurality of second lead portions, respectively;
a plurality of third wires electrically connecting the plurality of second pad electrodes of the first semiconductor chip with the plurality of fourth pad electrodes of the second semiconductor chip, respectively; and
a sealing portion sealing the first chip mounting portion, the second chip mounting portion, the first semiconductor chip, the second semiconductor chip, the plurality of first lead portions, the plurality of second lead portions, the plurality of first wires, the plurality of second wires and the plurality of third wires,
wherein the sealing portion has:
a first main surface; and
a second main surface opposite the first main surface, wherein the first chip mounting portion has:
a first thick portion; and
a first thin portion having a thickness thinner than a thickness of the first thick portion,
wherein the second chip mounting portion has:
a second thick portion; and
a second thin portion having a thickness thinner than a thickness of the second thick portion,
wherein the first thin portion and the second thin portion are arranged next to each other,
wherein the first semiconductor chip is mounted on the first chip mounting portion via a first bonding material so as to stride over the first thick portion and the first thin portion,
wherein the second semiconductor chip is mounted on the second chip mounting portion via a second bonding material so as to stride over the second thick portion and the second thin portion, and
wherein, at the first main surface of the sealing portion, each of the first thick portion of the first chip mounting portion and the second thick portion of the second chip mounting portion is exposed from the sealing portion, but each of the first thin portion of the first chip mounting portion and the second thin portion of the second chip mounting portion is not exposed from the sealing portion.

14. The semiconductor device according to claim 13, wherein a second electric power is to be supplied to the second semiconductor chip, the second electric power being larger than a first electric power which is to be supplied to the first semiconductor chip.

15. The semiconductor device according to claim 13,
wherein the plurality of first lead portions has a first lead,
wherein the plurality of second lead portions has a second lead,
wherein the first lead and the second lead are arranged next to each other, and
wherein a distance between the first lead and the second lead along an outer surface of the sealing portion is larger than a distance between the first chip mounting portion and the second chip mounting portion.

16. The semiconductor device according to claim 13, wherein, in plan view, the first thin portion of the first chip mounting portion and the second thin portion of the second chip mounting portion are arranged between the first thick portion of the first chip mounting portion and the second thick portion of the second chip mounting portion.

17. The semiconductor device according to claim 13, wherein the first main surface is a flat surface.

18. The semiconductor device according to claim 13,
wherein the first chip mounting portion has:
a first mounting surface for mounting the first semiconductor chip; and
a first back surface opposite the first mounting surface,
wherein the second chip mounting portion has:
a second mounting surface for mounting the second semiconductor chip; and
a second back surface opposite the second mounting surface,
wherein each of the first mounting surface and the second mounting surface is a flat surface,
wherein the first back surface has a step at a boundary between the first thick portion and the first thin portion, and
wherein the second back surface has a step at a boundary between the second thick portion and the second thin portion.

19. The semiconductor device according to claim 13, wherein, in cross-sectional view, the first chip mounting portion is located at a same height as the second chip mounting portion.

20. The semiconductor device according to claim 13, wherein a thickness of the first thick portion of the first chip mounting portion is a same as a thickness of the second thick portion of the second chip mounting portion.
